(19) United States
(12) Patent Application Publication
(10) Pub. No.: US 2024/0413121 A1
(43) Pub. Date: Dec. 12, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: CHIH-TING LAI, Hsinchu City (TW); Kris Lipu Chuang, Hsinchu City (TW); Yi-Che Chiang, Hsinchu (TW); Hsin Ting Lin, Hsinchu County (TW); Tsung-Yu Chen, Hsinchu City (TW)

(73) Assignee: Taiwan Semiconductor Manufacturing Company, Ltd., Hsinchu (TW)

(21) Appl. No.: 18/332,761

(22) Filed: Jun. 12, 2023

(51) Int. Cl. H01L 25/065; H01L 21/56; H01L 21/683; H01L 23/00; H01L 23/31

(52) U.S. Cl. CPC H01L 25/0652; H01L 21/56; H01L 21/6835; H01L 23/3107; H01L 24/20; H01L 24/32; H01L 24/73; H01L 2221/68381; H01L 2224/19; H01L 2224/32225; H01L 2224/73267

(57) ABSTRACT

A semiconductor device includes a supporting structure, a die stack, and a redistribution circuit structure. The die stack is disposed over the supporting structure and includes a first semiconductor die comprising a substrate and a second semiconductor die, where the first semiconductor die is between the second semiconductor die and the supporting structure, and a material of the supporting structure is different from a material of the substrate of the first semiconductor die. The redistribution circuit structure is disposed over the die stack and electrically coupled to the first semiconductor die and the second semiconductor die.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 11 are schematic cross-sectional views of various stages in a manufacturing method of a semiconductor device in accordance with some embodiments of the disclosure.

FIG. 12 is a schematic cross-sectional view showing a semiconductor device in accordance with alternative embodiments of the disclosure.

FIG. 13 is a schematic cross-sectional view showing a semiconductor device in accordance with alternative embodiments of the disclosure.

FIG. 14 is a schematic cross-sectional view showing a semiconductor device in accordance with alternative embodiments of the disclosure.

FIG. 15 is a schematic cross-sectional view showing a semiconductor device in accordance with alternative embodiments of the disclosure.

FIG. 16 is a schematic cross-sectional view showing a semiconductor device in accordance with alternative embodiments of the disclosure.

FIG. 17 is a schematic cross-sectional view showing a semiconductor device in accordance with alternative embodiments of the disclosure.

FIG. 18 is a schematic cross-sectional view showing a semiconductor device in accordance with alternative embodiments of the disclosure.

FIG. 19 is a schematic cross-sectional view showing a semiconductor device in accordance with alternative embodiments of the disclosure.

FIG. 20 is a schematic cross-sectional view showing an application of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor device (or a semiconductor structure) having a plurality of semiconductor dies integrated therein and a high performance carrier, where the plurality of semiconductor die are arranged into a die stack with multiple tiers and the high performance carrier is bonded to the die stack, and is not intended to limit the scope of the disclosure. Owing to the high performance carrier, during an operation of the semiconductor device or semiconductor structure, the heat generated by the plurality of semiconductor dies inside the die stack can be vertically drafted toward the high performance carrier and dissipated to an external environment, thereby the efficiency of a heat dissipation of the semiconductor device or semiconductor structure is improved. In addition, owing to the high performance carrier, the warpage of the semiconductor device or semiconductor structure can be controlled (or saying reduced) as the semiconductor device or semiconductor structure is further bonded to another electronical component (e.g., an external component or element such as a circuit board, an interposer, or the like) or as an thermal process is taken place in the manufacturing process of the semiconductor device or semiconductor structure.

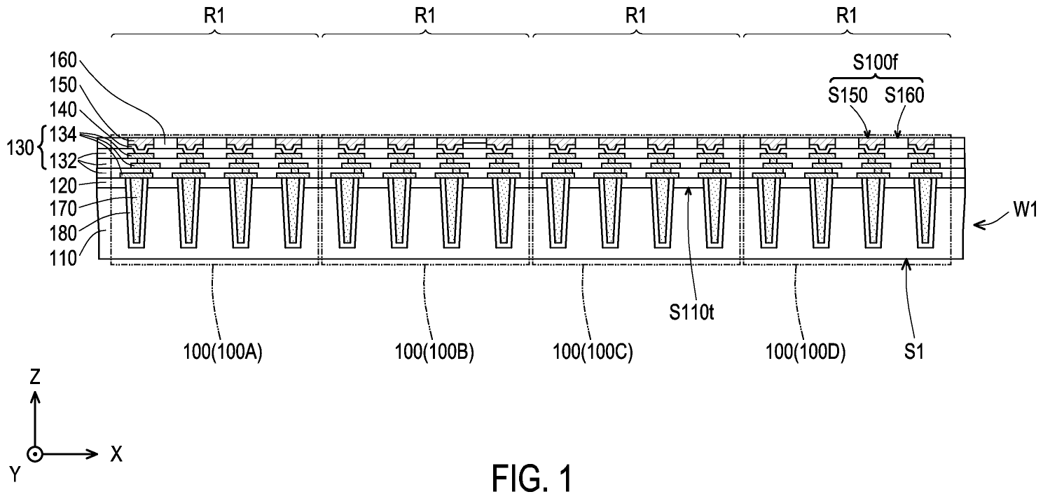

FIG. 1 to FIG. 11 are schematic cross-sectional views of various stages in a manufacturing method of a semiconductor device 1000A in accordance with some embodiments of the disclosure. In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Referring to FIG. 1, in some embodiments, a wafer W1 is provided. In some embodiments, if considering a plane view along a direction Z, the wafer W1 is in a wafer or panel form. The wafer W1 may be in a form of wafer with a wafer-size having a diameter of about 4 inches or more. The wafer W1 may be in a form of wafer with a wafer-size having a diameter of about 6 inches or more. The wafer W1 may be in a form of wafer with a wafer-size having a diameter of about 8 inches or more. Or alternatively, the wafer W1 may be in a form of wafer with a wafer-size having a diameter of about 12 inches or more. On the other hand, the wafer W1 may be in a form of panel (e.g., in a shape of rectangle at the plane view), with a panel-size having a long axis of about 4 inches or more, about 6 inches or more, about 8 inches or more, about 12 inches or more, or any other suitable size. Alternatively, the panel form may be in a shape of square (at the plane view), with an edge size of about 4 inches or more, about 6 inches or more, about 8 inches or more, about 12 inches or more, or any other suitable edge size. For a non-limiting example, the wafer W1 is processed in the form of a reconstructed wafer/panel. The disclosure is not limited thereto.

In some embodiments, the wafer W1 includes a plurality of device regions R1 arranged in a form of an array along a direction X and a direction Y, where each device region R1 is a pre-determined location for a semiconductor die or chip (e.g., semiconductor dies 100). The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction X and the direction Y may be referred to as horizontal directions or lateral directions, the direction Z may be referred to as a stacking direction or a vertical direction, and a X-Y plane defined by the direction X and the direction Y may be referred to as the plane (or top) view.

The device regions R1 of the wafer W1 are physically connected to one another, as shown in FIG. 1, for example. In FIG. 1, only four device regions R1 are shown for illustrative purposes, however the disclosure is not limited thereto. In some embodiments, the wafer W1 includes a semiconductor substrate 110, a device layer 120 disposed over the semiconductor substrate 110 and having semiconductor components (not shown) formed therein, an interconnect structure 130 disposed on the device layer 120 and over the semiconductor substrate 110, a plurality of connecting pads 140 formed on the interconnect structure 130, a plurality of connecting vias 150 formed on the connecting pads 140, a protection layer 160 disposed on the interconnect structure 130 and the connecting pads 140 and at least laterally covers the connecting vias 150, and a plurality of conductive pillars 170 formed (embedded) in the semiconductor substrate 110, and a plurality of liners 180 lining the conductive pillars 170. In some embodiments, the conductive pillars 170 penetrate through the device layer 120, as shown in FIG. 1. In such embodiments, the liners 180 separate the conductive pillars 170 from the device layer 120 and the semiconductor substrate 110. As an alternative, the conductive pillars 170 do not penetrate through the device layer 120. In the embodiment of which the conductive pillars 170 do not penetrate through the device layer 120, the liners 180 may only separate the conductive pillars 170 from the semiconductor substrate 110.

As shown in FIG. 1, for example, the semiconductor components of the device layer 120 are interconnected through the interconnect structure 130, the connecting vias 150 are electrically connected to the interconnect structure 130 through the connecting pads 140, the connecting vias 150 are electrically connected to the semiconductor components of the device layer 120 through the connecting pads 140 and the interconnect structure 130, and the conductive pillars 170 are electrically connected to the semiconductor components of the device layer 120 through the interconnect structure 130. In the alternative embodiment of which the conductive pillars 170 do not penetrate through the device layer 120, the semiconductor components of the device layer 120 are interconnected through the interconnect structure 130, the connecting vias 150 are electrically connected to the interconnect structure 130 through the connecting pads 140, the connecting vias 150 are electrically connected to the semiconductor components of the device layer 120 through the connecting pads 140 and the interconnect structure 130, and the conductive pillars 170 are electrically connected to the semiconductor components of the device layer 120 through physical contacts.

In some embodiments, the semiconductor substrate 110 includes a bulk semiconductor, a semiconductor-on-insulator (SOI) substrate, other supporting substrate (e.g., quartz, glass, etc.), combinations thereof, or the like, which may be doped or undoped. In some embodiments, the semiconductor substrate 110 includes an elementary semiconductor (e.g., silicon or germanium in a crystalline, a polycrystalline, or an amorphous structure, etc.), a compound semiconductor (e.g., silicon carbide, gallium arsenide, gallium phosphide, indium phosphide, indium arsenide, and/or indium antimonide, etc.), an alloy semiconductor (e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.), combinations thereof, or other suitable materials. The compound semiconductor substrate may have a multilayer structure, or the substrate may include a multilayer compound semiconductor structure. The alloy SiGe may be formed over a silicon substrate. The SiGe substrate may be strained.

In some embodiments, the device layer 120 includes the semiconductor components formed on (and/or partially formed in) the semiconductor substrate 110, where the semiconductor components include active components (e.g., transistors, diodes, memory, etc.) and/or passive components (e.g., capacitors, resistors, inductors, jumper, etc.), or other suitable electrical components. The device layer 120 may be disposed at an active surface S110t of the semiconductor substrate 110 proximal to the interconnect structure 130, as shown in FIG. 1. In some embodiments, the semiconductor substrate 110 has the active surface S110t and a bottom surface Si opposite to the active surface S110t along the stacking direction Z of the interconnect structure 130, the device layer 120 and the semiconductor substrate 110. In some embodiments, the device layer 120 is interposed between the interconnect structure 130 and the active surface S110t of the semiconductor substrate 110.

The device layer 120 may include circuitry (not shown) formed in a front-end-of-line (FEOL), and the interconnect structure 130 may be formed in a back-end-of-line (BEOL). In some embodiments, the interconnect structure 130 includes an inter-layer dielectric (ILD) layer formed over the device layer 120, and an inter-metallization dielectric (IMD) layer formed over the ILD layer. In some embodiments, the ILD layer and the IMD layer are formed of a low-K dielectric material or an extreme low-K (ELK) material, such as an oxide, silicon dioxide, borophosphosilicate glass (BPSG), phosphosilicate glass (PSG), fluorinated silicate glass (FSG), SiOₓC_{y} (where x>0, y>0), Spin-On-Glass, Spin-On-Polymers, silicon carbon material, compounds thereof, composites thereof, combinations thereof, or the like. The ILD layer and the IMD layer may include any suitable number of dielectric material layers which is not limited thereto.

In some embodiments, the interconnect structure 130 includes one or more dielectric layers 132 and one or more metallization layers 134 in alternation. The metallization layers 134 may be embedded in the dielectric layers 132. In some embodiments, the interconnect structure 130 is electrically coupled to the semiconductor components of the device layer 120 to one another and to external components (e.g., test pads, bonding conductors, etc.) formed thereon. For example, the metallization layers 134 in the dielectric layers 132 route electrical signals between the semiconductor components of the device layer 120. In addition, the metallization layers 134 in the dielectric layers 132 route electrical signals to the semiconductor components of the device layer 120 from the conductive pillars 170 and/or the connecting vias 150 or from the semiconductor components of the device layer 120 to the conductive pillars 170 and/or the connecting vias 150. The semiconductor components of the device layer 120 and the metallization layers 134 are interconnected to perform one or more functions including memory structures (e.g., a memory cell), processing structures (e.g., a logic cell), input/output (I/O) circuitry (e.g., an I/O cell), or the like. An uppermost layer of the interconnect structure 130 may be a passivation layer made of one or more suitable dielectric materials such as silicon oxide, silicon nitride, low-k dielectrics, polyimide (PI), combinations of these, or the like. In some embodiments, as shown in FIG. 1, the passivation layer (e.g., the uppermost layer of the dielectric layers 132) of the interconnect structure 130 has an opening exposing at least a portion of a topmost layer of the metallization layers 134 for further electrical connection.

The dielectric layers 132 may be PI, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. The etching process may include a dry etching, a wet etching, or a combination thereof. In some embodiments, the dielectric layers 132 are formed by suitable fabrication techniques such as spin-on coating, chemical vapor deposition (CVD) such as plasma-enhanced chemical vapor deposition (PECVD), or the like.

The metallization layers 134 may be made of conductive materials formed by electroplating or deposition, such as copper, copper alloy, aluminum, aluminum alloy, or combinations thereof, which may be patterned using a photolithography and etching process. The etching process may include a dry etching, a wet etching, or a combination thereof. In some embodiments, the metallization layers 134 are patterned copper layers or other suitable patterned metal layers. For example, the metallization layers 134 may be metal lines, metal vias, metal pads, metal traces, etc. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum, or zirconium, etc. The numbers of the dielectric layers 132 and the number of the metallization layers 134 are not limited in the disclosure, and may be selected and designated based on demand and design layout.

In some embodiments, as illustrated in FIG. 1, the connecting pads 140 are disposed over and electrically coupled to the topmost layer of the metallization layer 134 of the interconnect structure 130 exposed by the passivation layer (e.g., the uppermost layer of the dielectric layers 132) of the interconnect structure 130 for testing and/or further electrical connection. The connecting pads 140 may be made of aluminum, copper, or alloys thereof or the like, and may be formed by an electroplating process. The disclosure is not limited thereto. Some of the connecting pads 140 may be testing pads, and some of the connecting pads 140 may be conductive pads for further electrical connection. In alternative embodiments, the connecting pads 140 may be optional for simple structure and cost benefits. In such alternative embodiments, the connecting vias 150 may directly connect to the uppermost metallization layer 134.

In some embodiments, the connecting vias 150 are respectively disposed on and electrically connected to the connecting pads 140 for providing an external electrical connection to the circuitry and semiconductor components of the device layer 120. In one embodiment, the connecting vias 150 may be formed of conductive materials such as copper, gold, aluminum, the like, or combinations thereof, and may be formed by an electroplating process or the like. The connecting vias 150 may be bond vias, bond pads or bond bumps, or combinations thereof. The disclosure is not limited thereto. The connecting vias 150 may serve as bonding conductors for further electrical connection, and may be formed over the connecting pads 140 (serving as the conductive pads for further electrical connection). The connecting vias 150 may be electrically coupled to the semiconductor components of the device layer 120 through the interconnect structure 130 and the connecting pads 140.

Alternatively, both of the connecting pads 140 and the connecting vias 150 may be formed on the interconnect structure 130. For example, the connecting vias 150 are disposed on and electrically connected to the topmost layer of the metallization layer 134 of the interconnect structure 130 exposed by the passivation layer (e.g., the uppermost layer of the dielectric layers 132) of the interconnect structure 130. That is, the connecting vias 150 and the connecting pads 140 may all be disposed on the topmost layer of the metallization layer 134 of the interconnect structure 130 exposed by the passivation layer in a manner of side-by-side. In such embodiments, the connecting pads 140 may be testing pads for testing while the connecting vias 150 may be the bonding conductors for further electrical connection. The connecting vias 150 may be electrically coupled to the semiconductor components of the device layer 120 through the interconnect structure 130. The number of the connecting pads 140 and the number of the connecting vias 150 may be selected and designated based on the demand and design layout, and thus are not limited thereto.

In some embodiments, the protection layer 160 is formed on the interconnect structure 130 to cover the interconnect structure 130 and the connecting pads 140 exposed by the connecting vias 150 and at least laterally cover the connecting vias 150. That is to say, the protection layer 160 prevents any possible damage(s) occurring on the interconnect structure 130, the connecting pads 140 and the connecting vias 150 during the transfer of the wafer W1 including the semiconductor dies 100. In addition, in some embodiments, the protection layer 160 further acts as a passivation layer for providing better planarization and evenness. In some embodiments, top surfaces S150 of the connecting vias 150 are accessibly revealed by a top surface S160 of the protection layer 160, as shown in FIG. 1. In the case, the top surfaces S150 of the connecting vias 150 and the top surface S160 of the protection layer 160 together constitute a front side of the wafer W1 (also referred to as a front-side or an active side S100f of each of the semiconductor dies 100). However, the disclosure is not limited thereto; alternatively, the top surfaces S150 of the connecting vias 150 may not be accessibly revealed by the top surface S160 of the protection layer 160 for providing a further protection to the wafer W1 including the semiconductor dies 100 during the transfer thereof, where the connecting vias 150 would be accessibly revealed by the top surface S160 of the protection layer 160 for a later electrical connection by forming the front side (which constituted by leveling the top surfaces S150 of the connecting vias 150 and the top surface S160 of the protection layer 160, e.g., the front-sides or active sides S100f of the semiconductor dies 100) of the wafer W1 via a sequential process (such as a patterning process).

The protection layer 160 may include one or more layers of dielectric materials, such as silicon nitride, silicon oxide, high-density plasma (HDP) oxide, tetra-ethyl-ortho-silicate (TEOS), undoped silicate glass (USG), silicon oxynitride, PBO, PI, silicon carbon, silicon carbon oxynitride, diamond like carbon (DLC), and the like, or a combination thereof. It should be appreciated that the protection layer 160 may include etch stop material layer(s) (not shown) interposed between the dielectric material layers depending on the process requirements. For example, the etch stop material layer is different from the overlying or underlying dielectric material layer(s). The etch stop material layer may be formed of a material having a high etching selectivity relative to the overlying or underlying dielectric material layer(s) so as to be used to stop the etching of layers of dielectric materials.

In some embodiments, the conductive pillars 170 are embedded in the semiconductor substrate 110. For example, the conductive pillars 170 are formed in the semiconductor substrate 110 and extended from the active surface S110t toward the bottom surface S1 along the stacking direction Z. As shown in FIG. 1, the conductive pillars 170 may penetrate through the device layer 120 to electric connect the metallization layers 134 of the interconnect structure 130, and may be electrically connected to the semiconductor component(s) of the device layer 120 through the interconnect structure 130. In other words, the conductive pillars 170 are in physical contact with the bottommost layer of the metallization layers 134 of the interconnect structure 130 exposed by the lowest layer of the dielectric layers 132 of the interconnect structure 130, for example. That is, the conductive pillars 170 are electrically connected to the semiconductor component(s) of the device layer 120 through the interconnect structure 130, and are electrically connected to the connecting vias 150 through the interconnect structure 130 and the connecting pads 140, in some embodiments. The conductive pillars 170 may be formed of a conductive material, such as copper, tungsten, aluminum, silver, combinations thereof, or the like, which may be formed by plating or deposition (e.g., CVD).

However, the disclosure is not limited thereto; alternatively, the conductive pillars 170 may not penetrate through the device layer 120, where top surfaces of the conductive pillars 170 may be substantially level with (and/or substantially coplanar to) the active surface S110t of the semiconductor substrate 110 to directly connect to the semiconductor component(s) of the device layer 120. In such cases, the conductive pillars 170 may be electrically connected to the interconnect structure 130 through the semiconductor component(s) of the device layer 120.

As shown in FIG. 1, the conductive pillars 170 are not accessibly revealed by the bottom surface S1 of the semiconductor substrate 110, for example. However, the disclosure is not limited thereto, alternatively, the conductive pillars 170 may be accessibly revealed by the bottom surface S1 of the semiconductor substrate 110. The conductive pillars 170 may be tapered from the interconnect structure 130 to the bottom surface S1 of the semiconductor substrate 110, as illustrated in FIG. 1. Alternatively, the conductive pillars 170 have substantially vertical sidewalls.

In a cross-sectional view along the stacking direction Z, the shape of the conductive pillars 170 may depend on the demand and/or design layout/requirements, and is not intended to be limiting in the disclosure. For example, in the plane (top) view on an X-Y plane perpendicular to the stacking direction Z, the shape of the conductive pillars 170 is circular shape. However, depending on the design requirements, and the shape of the conductive pillars 170 may be an oval shape, a rectangular shape, a polygonal shape, or combinations thereof; the disclosure is not limited thereto. The number of the conductive pillars 170 is not limited to the drawings of the disclosure, which may be selected and designated based on the demand and design layout.

In some embodiments, each of the conductive pillars 170 is covered by the liner 180. For example, the liners 180 are formed between the conductive pillars 170 and the semiconductor substrate 110 and between the conductive pillars 170 and the device layer 120. In some embodiments, a sidewall of each of the conductive pillars 170 may be covered by the respective one liner 180. The liners 180 may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the liners 180 and the semiconductor substrate 110 and between the liners 180 and the device layer 120. In some embodiments, the conductive pillars 170, the liners 180 and the optional dielectric liner are formed by, but not limited to, forming recesses in the semiconductor substrate 110 and the device layer 120, respectively depositing the dielectric material, the barrier material, and the conductive material in the recesses, and removing excess materials on the device layer 120. For example, the recesses of the semiconductor substrate 110 and the device layer 120 are lined with the dielectric liner so as to laterally separate the liners 180 lining sidewalls and bottoms of the conductive pillars 170 from the semiconductor substrate 110 and the device layer 120. Alternatively, the liners 180 may be omitted. Or, alternatively, the conductive pillars 170 and the liners 180 may both be omitted.

The conductive pillars 170 are formed by using a via-first approach, in certain embodiments. The conductive pillars 170 may be formed prior to the formation of the interconnect structure 130. Alternatively, the conductive pillars 170 may be formed by using a via-last approach, and may be formed after the formation of interconnect structure 130.

In the alternative embodiments of which the conductive pillars 170 are accessibly revealed by the bottom surface S1 of the semiconductor substrate 110, the conductive pillars 170, the liners 180 and the optional dielectric liner are formed by, but not limited to, forming recesses in the semiconductor substrate 110 and the device layer 120, respectively depositing the dielectric material, the barrier material, and the conductive material in the recesses, removing excess materials on the device layer 120, and performing a patterning process to reveal the bottoms of the conductive pillars 170 from the semiconductor substrate 110. The patterning process may include a planarization process and/or etching process, the disclosure is not limited thereto.

For illustrative purposes, only four semiconductor dies 100 (also denoted as 100A, 100B, 100C, 100D, from left to right) are shown in FIG. 1 for simplicity, however the disclosure is not limited thereto. The number of the semiconductor dies 100 (e.g., 100A, 100B, 100C, 100D) may be selected and designated based on demand and design layout. In some embodiments, each of the semiconductor dies 100 (e.g., 100A, 100B, 100C, 100D) includes the semiconductor substrate 110, the device layer 120, the interconnect structure 130, the connecting pads 140, the connecting vias 150, the protection layer 160, the conductive pillars 170 and the liners 180, as shown in FIG. 1.

The semiconductor dies 100 (e.g., 100A, 100B, 100C, 100D) may be referred to as semiconductor dies or chips, independently, including a digital chip, an analog chip, or a mixed signal chip. In some embodiments, the semiconductor dies 100 (e.g., 100A, 100B, 100C, 100D) are, independently, a logic die such as a central processing unit (CPU), a graphics processing unit (GPU), a neural network processing unit (NPU), a deep learning processing unit (DPU), a tensor processing unit (TPU), a system-on-a-chip (SoC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies 100 (e.g., 100A, 100B, 100C, 100D) are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O memory (WIO); a pre-stacked memory cube such as a hybrid memory cube (HMC) module, or a high bandwidth memory (HBM) module; a combination thereof; or the like. In further alternative embodiments, the semiconductor dies 100 (e.g., 100A, 100B, 100C, 100D) are, independently, an artificial intelligence (AI) engine such as an AI accelerator; a computing system such as an AI server, a high-performance computing (HPC) system, a high power computing device, a cloud computing system, a networking system, an edge computing system, a immersive memory computing system (ImMC), etc.; a combination thereof; or the like. In some other embodiments, the semiconductor dies 100 (e.g., 100A, 100B, 100C, 100D) are, independently, an electrical and/or optical input/output (I/O) interface die, an integrated passives die (IPD), a voltage regulator die (VR), a local silicon interconnect die (LSI) with or without deep trench capacitor (DTC) features, a local silicon interconnect die (LSI) with multi-tier functions such as electrical and/or optical network circuit interfaces, IPD, VR, DTC, or the like. The types of the semiconductor dies 100 (e.g., 100A, 100B, 100C, 100D) may be selected and designated based on the demand and design requirement, and thus are not specifically limited in the disclosure.

In accordance with some embodiments of the disclosure, the types of some of the semiconductor dies 100 (e.g., 100A, 100B, 100C, 100D) are different from each other, while some of the semiconductor dies 100 (e.g., 100A, 100B, 100C, 100D) are identical types. In alternative embodiments, the types of all of the semiconductor dies 100 (e.g., 100A, 100B, 100C, 100D) are different. In further alternative embodiments, the types of all of the semiconductor dies 100 (e.g., 100A, 100B, 100C, 100D) are identical. In accordance with some embodiments of the disclosure, the sizes of some of the semiconductor dies 100 (e.g., 100A, 100B, 100C, 100D) are different from each other, while some of the semiconductor dies 100 (e.g., 100A, 100B, 100C, 100D) are the same sizes. In alternative embodiments, the sizes of all of the semiconductor dies 100 (e.g., 100A, 100B, 100C, 100D) are different. In further alternative embodiments, the sizes of all of the semiconductor dies 100 (e.g., 100A, 100B, 100C, 100D) are the same. In accordance with some embodiments of the disclosure, the shapes of some of the semiconductor dies 100 (e.g., 100A, 100B, 100C, 100D) are different from each other, while the shapes of some of the semiconductor dies 100 (e.g., 100A, 100B, 100C, 100D) are identical. In alternative embodiments, the shapes of all of the semiconductor dies 100 (e.g., 100A, 100B, 100C, 100D) are different. In further alternative embodiments, the shapes of all of the semiconductor dies 100 (e.g., 100A, 100B, 100C, 100D) are identical. The types, sizes and shapes of each of the semiconductor dies 100 (e.g., 100A, 100B, 100C, 100D) are independent from each other, and may be selected and designed based on the demand and design layout, the disclosure is not limited thereto.

In some embodiments, the semiconductor dies 100 are arranged aside to each other along the direction X and/or the direction Y. The semiconductor dies 100 may be arranged in an array. For a non-limiting example, the semiconductor dies 100 are arranged in the form of a matrix, such as a N×N array or a N×M array (N, M>0, N may or may not be equal to M) along the direction X and the direction Y. In some embodiments, the semiconductor dies 100 arranged in immediately adjacent rows and/or columns are positioned in an alignment manner (e.g. an array form) on the X-Y plane. In some other embodiments, the semiconductor dies 100 arranged in immediately adjacent rows and/or columns are positioned in a staggered manner (e.g. a staggered form) on the X-Y plane.

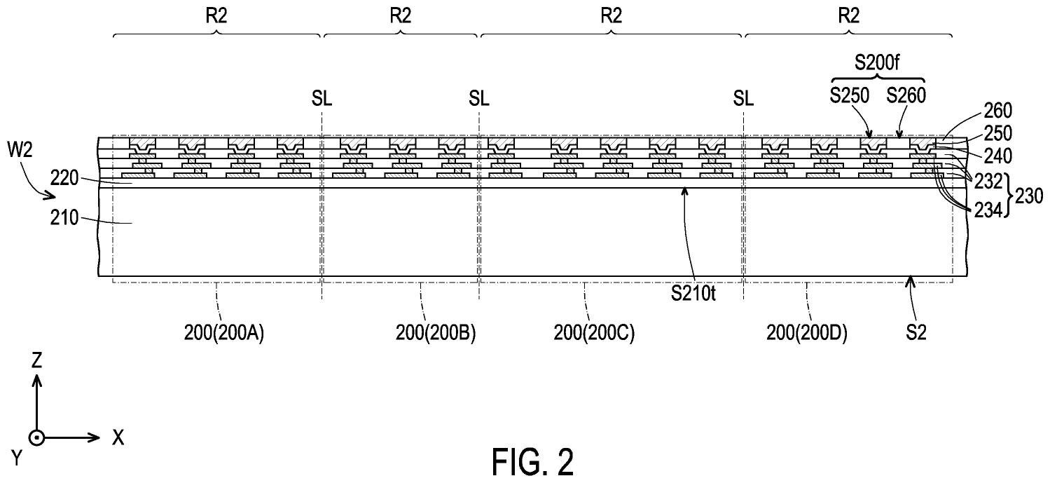

Referring to FIG. 2, in some embodiments, a wafer W2 is provided. In some embodiments, if considering a plane view along the direction Z, the wafer W2 is in a wafer or panel form. The wafer W2 may be in a form of wafer with a wafer-size having a diameter of about 4 inches or more. The wafer W2 may be in a form of wafer with a wafer-size having a diameter of about 6 inches or more. The wafer W2 may be in a form of wafer with a wafer-size having a diameter of about 8 inches or more. Or alternatively, the wafer W2 may be in a form of wafer with a wafer-size having a diameter of about 12 inches or more. On the other hand, the wafer W2 may be in a form of panel (e.g., in a shape of rectangle at the plane view), with a panel-size having a long axis of about 4 inches or more, about 6 inches or more, about 8 inches or more, about 12 inches or more, or any other suitable size. Alternatively, the panel form may be in a shape of square (at the plane view), with an edge size of about 4 inches or more, about 6 inches or more, about 8 inches or more, about 12 inches or more, or any other suitable edge size. For a non-limiting example, the wafer W2 is processed in the form of a reconstructed wafer/panel. The disclosure is not limited thereto.

In some embodiments, the wafer W2 includes a plurality of device regions R2 arranged in a form of an array along the direction X and the direction Y, where each device region R2 is a pre-determined location for a semiconductor die or chip (e.g., semiconductor dies 200). The device regions R2 of the wafer W2 are physically connected to one another, as shown in FIG. 2, for example. In FIG. 2, only four device regions R2 are shown for illustrative purposes, however the disclosure is not limited thereto. In some embodiments, the wafer W2 includes a semiconductor substrate 210, a device layer 220 disposed over the semiconductor substrate 210 and having semiconductor components (not shown) formed therein, an interconnect structure 230 (including one or more dielectric layers 232 and one or more metallization layers 234 in alternation) disposed on the device layer 220 and over the semiconductor substrate 210, a plurality of connecting pads 240 formed on the interconnect structure 230, a plurality of connecting vias 250 formed on the connecting pads 240, and a protection layer 260 disposed on the interconnect structure 230 and the connecting pads 240 and at least laterally covers the connecting vias 250. The device layer 220 may be disposed at an active surface S210t of the semiconductor substrate 210 proximal to the interconnect structure 230, as shown in FIG. 2. In some embodiments, the semiconductor substrate 210 has the active surface S210t and a bottom surface S2 opposite to the active surface S210t along the stacking direction Z of the interconnect structure 230, the device layer 220 and the semiconductor substrate 210. In some embodiments, the device layer 220 is interposed between the interconnect structure 230 and the active surface S210t of the semiconductor substrate 210. For example, the semiconductor components of the device layer 220 are interconnected through the interconnect structure 230, the connecting vias 250 are electrically connected to the interconnect structure 230 through the connecting pads 240, and the connecting vias 250 are electrically connected to the semiconductor components of the device layer 220 through the connecting pads 240 and the interconnect structure 230.

In some embodiments, top surfaces S250 of the connecting vias 250 are accessibly revealed by a top surface S260 of the protection layer 260, as shown in FIG. 2. In the case, the top surfaces S250 of the connecting vias 250 and the top surface S260 of the protection layer 260 together constitute a front side of the wafer W2 (also referred to as a front-side or an active side S200f of each of the semiconductor dies 200). However, the disclosure is not limited thereto; alternatively, the top surfaces S250 of the connecting vias 250 may not be accessibly revealed by the top surface S260 of the protection layer 260 for providing a further protection to the wafer W2 including the semiconductor dies 200 during the transfer thereof, where the connecting vias 250 would be accessibly revealed by the top surface S260 of the protection layer 260 for a later electrical connection by forming the front side (which constituted by leveling the top surfaces S250 of the connecting vias 250 and the top surface S260 of the protection layer 260, e.g., the front-sides or active sides S200f of the semiconductor dies 200) of the wafer W2 via a sequential process (such as a patterning process).

The detail, formation and material of each of the semiconductor substrate 210, the device layer 220, the interconnect structure 230 (e.g., the dielectric layers 232 and the metallization layers 234), the connecting pads 240, the connecting vias 250 and the protection layer 260 of the wafer W2 are respectively similar to or substantially identical to the detail, formation and material of each of the semiconductor substrate 110, the device layer 120, the interconnect structure 130 (e.g., the dielectric layers 132 and the metallization layers 134), the connecting pads 140, the connecting vias 150 and the protection layer 160 of the wafer W1 previously described in FIG, 1, and thus are not repeated herein for brevity. In alternative embodiments, the wafer W2 may include optional conductive pillars embedded in the semiconductor substrate 210 to electrically connect to the device layer 220 and optional liners lining the optional conductive pillars to separate the optional conductive pillars from the semiconductor substrate 210. In addition, the optional dielectric liners may be formed only between the optional liners and the optional semiconductor substrate. The detail, formation and material of each of the optional conductive pillars, the optional liners and the optional dielectric liners of the wafer W2 are respectively similar to or substantially identical to the detail, formation and material of each of the conductive pillars 170, the liners 180 and the optional dielectric liners of the wafer W1 previously described in FIG, 1, and thus are not repeated herein for brevity.

For illustrative purposes, only four semiconductor dies 200 (also denoted as 200A, 200B, 200C, 200D, from left to right) are shown in FIG. 2 for simplicity, however the disclosure is not limited thereto. The number of the semiconductor dies 200 (e.g., 200A, 200B, 200C, 200D) may be selected and designated based on demand and design layout. The semiconductor dies 200 (e.g., 200A, 200B, 200C, 200D) may be referred to as semiconductor dies or chips, independently, including a digital chip, an analog chip, or a mixed signal chip. In some embodiments, the semiconductor dies 200 (e.g., 200A, 200B, 200C, 200D) are, independently, a logic die such as a central processing unit (CPU), a graphics processing unit (GPU), a neural network processing unit (NPU), a deep learning processing unit (DPU), a tensor processing unit (TPU), a system-on-a-chip (SoC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies 200 (e.g., 200A, 200B, 200C, 200D) are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O memory (WIO); a pre-stacked memory cube such as a hybrid memory cube (HMC) module, or a high bandwidth memory (HBM) module; a combination thereof; or the like. In further alternative embodiments, the semiconductor dies 200 (e.g., 200A, 200B, 200C, 200D) are, independently, an artificial intelligence (AI) engine such as an AI accelerator; a computing system such as an AI server, a high-performance computing (HPC) system, a high power computing device, a cloud computing system, a networking system, an edge computing system, a immersive memory computing system (ImMC), etc.; a combination thereof; or the like. In some other embodiments, the semiconductor dies 200 (e.g., 200A, 200B, 200C, 200D) are, independently, an electrical and/or optical input/output (I/O) interface die, an integrated passives die (IPD), a voltage regulator die (VR), a local silicon interconnect die (LSI) with or without deep trench capacitor (DTC) features, a local silicon interconnect die (LSI) with multi-tier functions such as electrical and/or optical network circuit interfaces, IPD, VR, DTC, or the like. The types of the semiconductor dies 200 (e.g., 200A, 200B, 200C, 200D) may be selected and designated based on the demand and design requirement, and thus are not specifically limited in the disclosure.

In accordance with some embodiments of the disclosure, the types of some of the semiconductor dies 200 (e.g., 200A, 200B, 200C, 200D) are different from each other, while some of the semiconductor dies 200 (e.g., 200A, 200B, 200C, 200D) are identical types. In alternative embodiments, the types of all of the semiconductor dies 200 (e.g., 200A, 200B, 200C, 200D) are different. In further alternative embodiments, the types of all of the semiconductor dies 200 (e.g., 200A, 200B, 200C, 200D) are identical. In accordance with some embodiments of the disclosure, the sizes of some of the semiconductor dies 200 (e.g., 200A, 200B, 200C, 200D) are different from each other, while some of the semiconductor dies 200 (e.g., 200A, 200B, 200C, 200D) are the same sizes. In alternative embodiments, the sizes of all of the semiconductor dies 200 (e.g., 200A, 200B, 200C, 200D) are different. In further alternative embodiments, the sizes of all of the semiconductor dies 200 (e.g., 200A, 200B, 200C, 200D) are the same. In accordance with some embodiments of the disclosure, the shapes of some of the semiconductor dies 200 (e.g., 200A, 200B, 200C, 200D) are different from each other, while the shapes of some of the semiconductor dies 200 (e.g., 200A, 200B, 200C, 200D) are identical. In alternative embodiments, the shapes of all of the semiconductor dies 200 (e.g., 200A, 200B, 200C, 200D) are different. In further alternative embodiments, the shapes of all of the semiconductor dies 200 (e.g., 200A, 200B, 200C, 200D) are identical. The types, sizes and shapes of each of the semiconductor dies 200 (e.g., 200A, 200B, 200C, 200D) are independent from each other, and may be selected and designed based on the demand and design layout, the disclosure is not limited thereto.

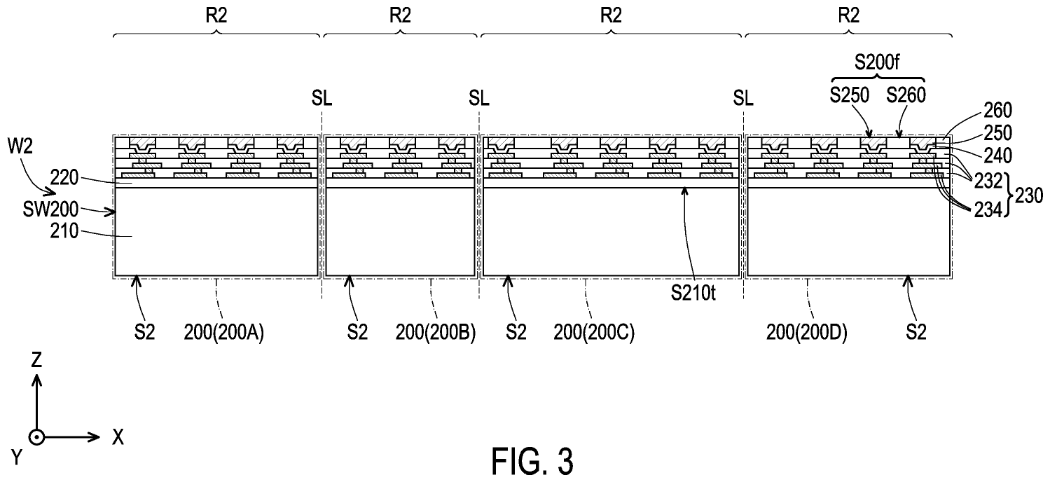

Referring to FIG. 2 and FIG. 3 together, in some embodiments, a dicing (or singulation) process is sequentially performed along scribe lines SL to cut through the wafer W2, thereby forming individual and separated semiconductor dies 200 (e.g., 200A, 200B, 200C, 200D) corresponding to the device regions R2. For example, each of the semiconductor dies 200 (e.g., 200A, 200B, 200C, 200D) includes the semiconductor substrate 210, the device layer 220, the interconnect structure 230, the connecting pads 240, the connecting vias 250, and the protection layer 260. The dicing (or singulation) process may be or include a wafer dicing process including mechanical blade sawing or laser cutting. The disclosure is not limited thereto.

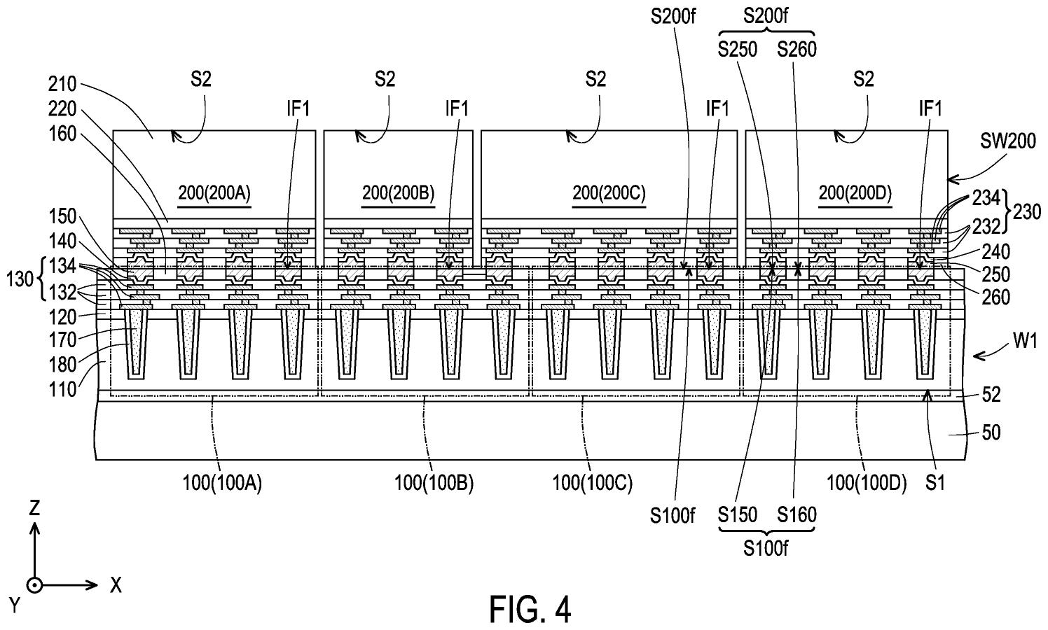

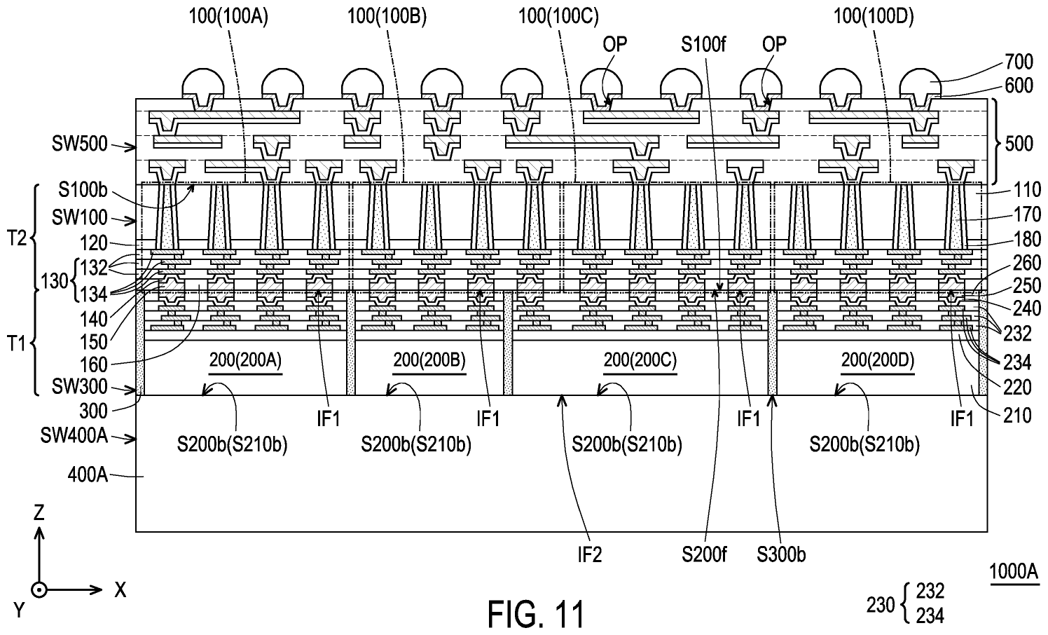

Referring to FIG. 4, in some embodiments, a carrier 50 is provide. In some embodiments, the carrier 50 may be a glass carrier, a ceramic carrier, or any suitable carrier for carrying a semiconductor wafer or a reconstituted wafer for the manufacturing method of the semiconductor device (or structure), such as the semiconductor device 1000A depicted in FIG. 11. In alternative embodiments, the carrier 50 may be a reclaim wafer or a reconstituted wafer for the manufacturing method of the semiconductor device (or structure). Or, the carrier 50 may be a silicon substrate. In some embodiments, the carrier 50 is a temporary supporting structure, which is removed during the manufacturing method of the semiconductor device 1000A. The carrier 50 may be refer to as a temporary carrier.

In some embodiments, the carrier 50 is coated with a debond layer 52 (as shown in FIG. 4). The material of the debond layer 52 may be any material suitable for bonding and debonding the carrier 50 from the above layer(s) or any wafer(s) disposed thereon. In some embodiments, the debond layer 52 includes a dielectric material layer made of a dielectric material including any suitable polymer-based dielectric material (such as BCB, PBO). For a non-limiting example, the debond layer 52 includes a dielectric material layer made of an epoxy-based thermal-release material, which loses its adhesive property when heated, such as a light-to-heat-conversion (LTHC) release coating film. For another non-limiting example, the debond layer 52 includes a dielectric material layer made of an ultra-violet (UV) glue, which loses its adhesive property when exposed to UV lights. The debond layer 52 may be dispensed as a liquid and cured on the carrier 50, may be a laminate film laminated onto the carrier 50, or may be formed on the carrier 50 by any suitable method. For example, as shown in FIG. 4, an illustrated top surface of the debond layer 52, which is opposite to an illustrated bottom surface contacting the carrier 50, is leveled and has a high degree of coplanarity. In certain embodiments, the debond layer 52 is a LTHC layer with good chemical resistance, and such layer enables room temperature debonding from the carrier 50 by applying laser irradiation, however the disclosure is not limited thereto. For example, the debond layer 52 includes a LTHC layer.

In an alternative embodiment, a buffer layer (not shown) is coated on the debond layer 52, where the debond layer 52 is sandwiched between the buffer layer and the carrier 50, and a top surface of the buffer layer may further provide a high degree of coplanarity. In some embodiments, the buffer layer may be a dielectric material layer. In some embodiments, the buffer layer may be a polymer layer which made of polyimide (PI), PBO, BCB, or any other suitable polymer-based dielectric material. In some embodiments, the buffer layer may be Ajinomoto Buildup Film (ABF), Solder Resist film (SRF), or the like. In other words, the buffer layer is an optional dielectric layer, and may be omitted based on the demand; the disclosure is not limited thereto. For example, the buffer layer may be formed by a suitable fabrication technique such as spin-coating, lamination, deposition, or the like.

In some embodiments, the wafer W1 is placed onto the debond layer 52 and over the carrier 50. For example, the bottom surfaces S1 of the semiconductor substrates 110 of the semiconductor dies 100 (e.g., 100A through 100D) are disposed on (e.g., in physical contact with) the debond layer 52 and over the carrier 50. As shown in FIG. 4, the front-sides S100f of the semiconductor dies 100 are facing upward and are accessibly revealed, for example. Thereafter, at least one semiconductor die 200 is provided and placed onto the wafer W1 and over the carrier 50, in some embodiments. For example, as shown in FIG. 4, four semiconductor dies 200 (e.g., 200A through 200D) are picked-and-placed over on the wafer W1 and over the carrier 50, where the front sides S200f of the semiconductor dies 200 directly prop against the front side of the wafer W1 (e.g., the front sides S100f of the semiconductor dies 100), for example. The number of the semiconductor dies 200 placed onto the semiconductor dies 100 may be selected and designated based on demand and design layout, which may be more than four or less than four.

In some embodiments, the semiconductor dies 200 are arranged aside to each other along the direction X and/or the direction Y. The semiconductor dies 200 may be arranged in an array. For one non-limiting example, the semiconductor dies 200 are arranged in the form of a matrix, such as an N′×N′ array or an N′×M′ array (N′, M′>0, N′ may or may not be equal to M′) along the direction X and the direction Y. In some embodiments, the semiconductor dies 200 arranged in immediately adjacent rows and/or columns are positioned in an alignment manner (e.g. an array form) on the X-Y plane. In some other embodiments, the semiconductor dies 200 arranged in immediately adjacent rows and/or columns are positioned in a staggered manner (e.g. a staggered form) on the X-Y plane. In further other embodiments, the semiconductor dies 200 are arranged into a pre-determined pattern in a concentric manner, where at least one of the semiconductor dies 200 is located at the center (of the wafer W1 in a vertical projection along direction Z) and surrounded by the other semiconductor dies 200 on the X-Y plane, and the semiconductor dies 200 surrounding the at least one of the semiconductor dies 200 being located at the center are in radial arrangement.

After the placement of the semiconductor dies 200 over the wafer W1, a bonding process is performed to bond the semiconductor dies 200 to the wafer W1, in some embodiments. For example, the semiconductor dies 200 (e.g., 200A through 200D) each are electrically connected to and electrically communicated to one or more of the semiconductor dies 100 of the wafer W1. As shown in FIG. 4, the semiconductor die 200A may be electrically connected to and electrically communicated to the semiconductor die 100A, the semiconductor die 200B may be electrically connected to and electrically communicated to the semiconductor die 100B, the semiconductor die 200C may be electrically connected to and electrically communicated to the semiconductor die 100B and the semiconductor die 100C, and the semiconductor die 200D may be electrically connected to and electrically communicated to the semiconductor die 100D. In the case, the semiconductor die 200C may be extended from the semiconductor die 100B to the semiconductor die 100C in the vertical projection along the direction Z, where the semiconductor die 200C may be referred to as a bridge die (or chip) or a semiconductor bridge die (or chip). In other words, the semiconductor dies 100 (e.g., 100A through 100D) each may be electrically connected to and electrically communicated to one or more of the semiconductor dies 200 overlying thereto. In the case, there may be at least one of the semiconductor dies 100 (e.g., 100A through 100D) electrically connected to and electrically communicated to more than one of the semiconductor dies 200 overlying thereto, which may be referred to as a bridge die (or chip) or a semiconductor bridge die (or chip). Or alternatively, there is no bridge die (or chip) or semiconductor bridge die (or chip). As shown in FIG. 4, the front-sides S200f of the semiconductor dies 200 are facing downward and prop against the front-sides S100f of the semiconductor dies 100, for example.

For example, the semiconductor dies 200 are bonded to the semiconductor dies 100 by bonding process including both of a metal-to-metal bonding and a dielectric-to-dielectric bonding. As shown in FIG. 4, each of the semiconductor dies 200 (e.g., 200A, 200B, 200C and 200D) is disposed on (e.g., in physical contact with) and electrically connected to one or more respective semiconductor dies 100 (e.g., 100A, 100B, 100C and 100D) underlying thereto. In some embodiments, as shown in FIG. 4, the top surfaces S250 of the connecting vias 250 of the semiconductor dies 200 respectively prop against the top surfaces S150t of the connecting vias 150 of the semiconductor dies 100 underlying thereto, where the top surfaces S250 of the connecting vias 250 of the semiconductor dies 200 and the top surfaces S150t of the connecting vias 150 of the semiconductor dies 100 underlying thereto are bonded together through direct metal-to-metal bonding (such as a copper-to-copper bonding). In addition, as shown in FIG. 4, the top surfaces S260 of the protection layers 260 (laterally covering the connecting vias 250) of the semiconductor dies 200 respectively prop against the top surfaces S160 of the protection layers 160 (laterally covering the connecting vias 150) of the semiconductor dies 100 underlying thereto, where the top surfaces S260 of the protection layers 260 of the semiconductor dies 200 and the top surfaces S160 of the protection layers 160 of the semiconductor dies 100 underlying thereto are bonded together through a direct dielectrics-to-dielectrics bonding (such as an oxide-to-oxide bonding, a nitride-to-nitride bonding, or an oxide-to-nitride bonding), for example. In such embodiments, a bonding interface IF1 between the semiconductor dies 200 (e.g., 200A, 200B, 200C and 200D) and the semiconductor dies 100 (e.g., 100A, 100B, 100C and 100D) includes a dielectric-to-dielectric bonding interface (or a dielectric-to-dielectric bonding region) (e.g., an oxide-to-oxide bonding interface, a nitride-to-nitride bonding interface, or an oxide-to-nitride bonding interface) and a metal-to-metal bonding interface (or a metal-to-metal bonding region) (e.g., a copper-to-copper bonding interface).

It should be noted that bonding methods described above are merely examples and are not intended to be limiting. An offset may present between sidewalls of the connecting vias 150 and a sidewall of the connecting vias 250 overlying thereto, see FIG. 4. Since one of the connecting vias 150 and the connecting vias 250 may have a larger bonding surface than the other one, the direct metal-to-metal bonding may still be achieved even if misalignment occurs, thereby the reliability of electrical connections between the semiconductor dies 100 and the semiconductor dies 200 can be ensured. With such, for certain embodiments, either the protection layer 160 immediately adjacent to the connecting vias 150 is bonded to a portion of each of the connecting vias 250 (e.g., a dielectric-to-metal bonding), or the protection layer 260 immediately adjacent to the connecting vias 250 is bonded to a portion of each of the connecting vias 150 (e.g., a dielectric-to-metal bonding), see FIG. 4.

However, the disclosure is not limited thereto; alternatively, the semiconductor dies 200 may be bonded to the semiconductor dies 100 by flip-chip (FC) bonding. In the alternative embodiments, a plurality of joints (not shown) are presented between the connecting vias 250 of the semiconductor dies 200 and the connecting vias 150 of the semiconductor dies 100 underlying thereto for mechanically connecting and electrically connecting the semiconductor dies 200 and the semiconductor dies 100. The joints may include micro-bumps, metal pillars, electroless nickel-electroless palladium-immersion gold (ENEPIG) formed bumps, controlled collapse chip connection (C4) bumps (for example, which may have, but not limited to, a size of about 80 μm), a ball grid array (BGA) bumps or balls (for example, which may have, but not limited to, a size of about 400 μm), solder balls, or the like. The disclosure is not limited thereto. When solder is used, the solder may include either eutectic solder or non-eutectic solder. The solder may include lead or be lead-free, and may include Sn—Ag, Sn—Cu, Sn—Ag—Cu, or the like. When solder is used, the joints may be referred to as solder joints or solder regions. In such alternative embodiments, an underfill (not show) may be optionally applied to wrap sidewalls of the joints to ensure the adhesion strength between the semiconductor dies 200 and the semiconductor dies 100 electrically connected thereto.

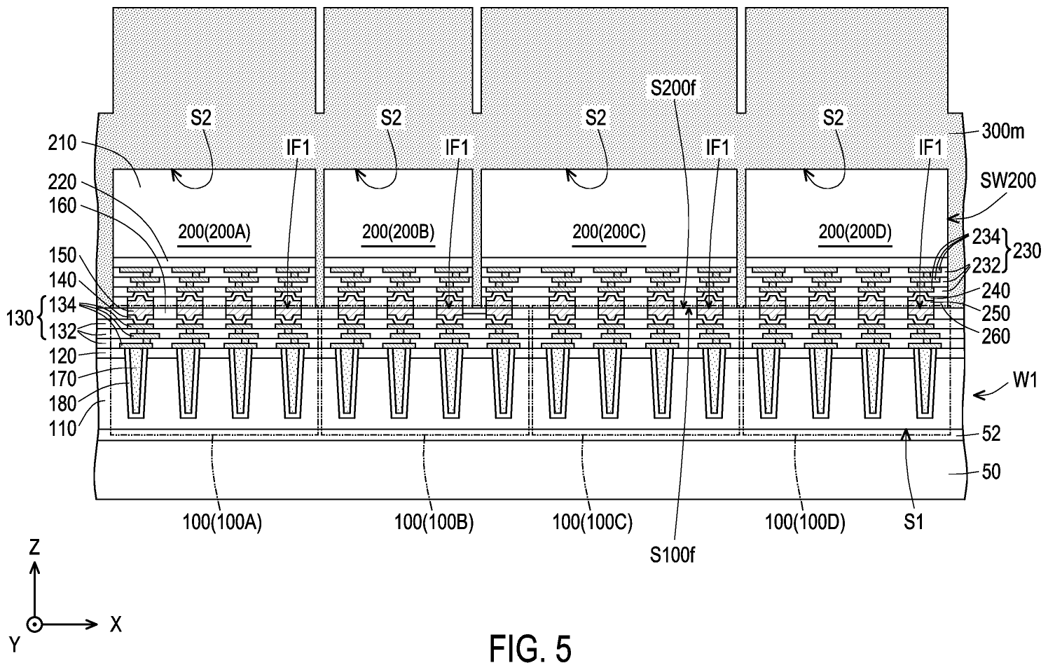

Referring to FIG. 5, in some embodiments, the semiconductor dies 200 are encapsulated in an insulating material. In some embodiments, an insulating encapsulation 300m is conformally formed on the semiconductor dies 200 and over the carrier 50, where the wafer W1 (including the semiconductor dies 100) exposed by the semiconductor dies 200 are completely covered by the insulating encapsulation 300m. The insulating encapsulation 300m may be made of a dielectric material (such as an oxide (e.g., silicon oxide), a nitride (e.g., silicon nitride), TEOS, or the like) or any suitable insulating materials for gap fill, and may be formed by deposition (such as a CVD process). As shown in FIG. 5, the front side (where the front-sides S100f of the semiconductor dies 100 located at) of the wafer W1 exposed by the semiconductor dies 200 and the bottom surface S2 (e.g., of the semiconductor substrates 210) and sidewalls SW200 of the semiconductor dies 200 are not accessibly revealed by the insulating encapsulation 300m, for example.

Alternatively, the insulating encapsulation 300m may be a molding compound, a molding underfill, a resin (such as epoxy-based resin), or the like, which may be formed by a molding process. The molding process may include a compression molding process or a transfer molding process. The insulating encapsulation 300m may include polymers (such as epoxy resins, phenolic resins, silicon-containing resins, or other suitable resins) or other suitable materials. Alternatively, the insulating encapsulation 300m may include an acceptable insulating encapsulation material. In some embodiments, the insulating encapsulation 300m further includes inorganic filler or inorganic compound (e.g. silica, clay, and so on) which can be added therein to optimize coefficient of thermal expansion (CTE) of the insulating encapsulation 300m. The disclosure is not limited thereto. As an alternative, the insulating encapsulation 300m may be a multi-layered structure and include a plurality of stacked dielectric layers. The stacked dielectric layers may be formed from multiple layers of a single dielectric material. Or, the stacked dielectric layers may be formed from multiple layers of different dielectric materials arranged in alternation.

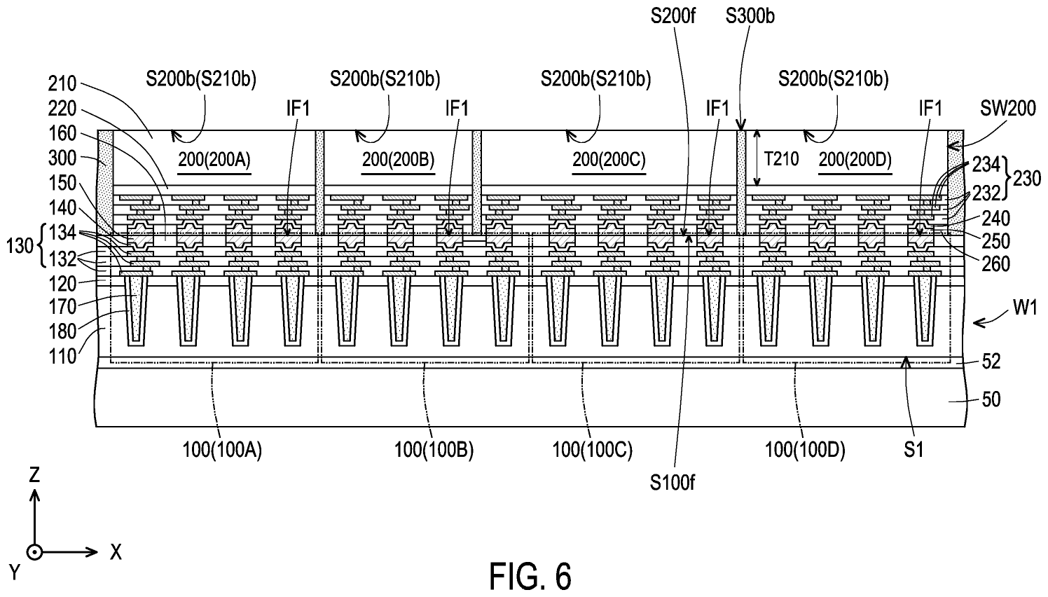

Referring to FIG. 5 and FIG. 6, in some embodiments, a planarization process is performed on the insulating encapsulation 300m to form an insulating encapsulation 300 having a surface S300b exposing the semiconductor dies 200. The insulating encapsulation 300 is disposed on the wafer W1 to laterally cover the semiconductor dies 200 (e.g., the sidewalls SW200), for example. In other words, the sidewalls SW200 of the semiconductor dies 200 are in physical contact with the insulating encapsulation 300, where the bottom surface S2 of the semiconductor dies 200 is accessibly revealed by the insulating encapsulation 300. In some embodiments, the insulating encapsulation 300m is planarized by a mechanical grinding process, a chemical mechanical polishing (CMP) process, an etching process, and/or combinations thereof. The etching process may include a dry etching, a wet etching, or a combination thereof. In some embodiments, during the planarization process of the insulating encapsulation 300m, the semiconductor substrates 210 of the semiconductor dies 200 are also planarized.

In other words, during the planarization process of the insulating encapsulation 300m, the semiconductor substrates 210 of the semiconductor dies 200 may be thinned down, where a thickness T200 of each of the semiconductor substrates 210 of the semiconductor dies 200 may be approximately ranging from 6 μm to 100 μm after planarizing, although other suitable thickness may alternatively be utilized. As shown in FIG. 6, for example, the surface S300b of the insulating encapsulation 300 is substantially level with a bottom surface S210b of each of the semiconductor substrates 210 of the semiconductor dies 200. In some embodiments, the surface S300b of the insulating encapsulation 300 is substantially coplanar to the bottom surfaces S210b of the semiconductor substrates 210 of the semiconductor dies 200. The bottom surfaces S210b of the semiconductor substrates 210 may be referred to as back-sides, rear-sides, or non-active sides S200b of the semiconductor dies 200. For example, in the direction Z, the front sides S200f of the semiconductor dies 200 are opposite to the back sides S200b of the semiconductor dies 200, as shown in FIG. 6. In some embodiments, a back side of the wafer W2 is where the back-sides S200b of the semiconductor dies 200 located at.

In some embodiments, after the planarization process, a cleaning step may be optionally performed to clean and remove the residue generated from the planarization process. However, the disclosure is not limited thereto, and the planarization process may be performed through any other suitable method.

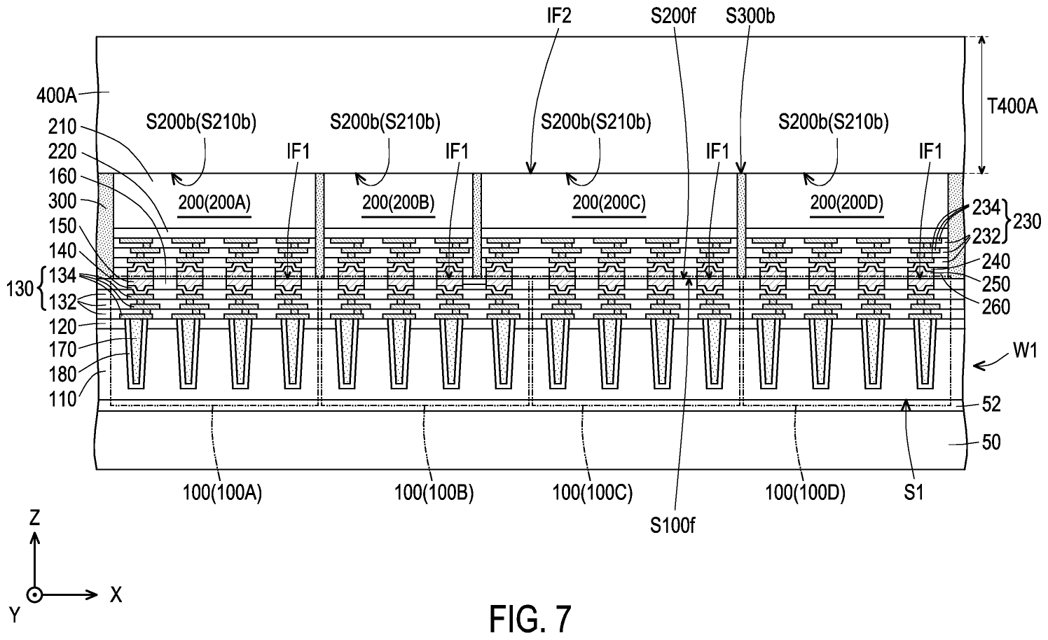

Referring to FIG. 7, in some embodiments, a supporting structure 400A is provided on the insulating encapsulation 300 and over the carrier 50. For example, after the supporting structure 400A is placed onto (e.g., in physical contact with) the semiconductor dies 200 and the insulating encapsulation 300 laterally encapsulating the semiconductor dies 200, the supporting structure 400A is bonded to the semiconductor dies 200 by performing a thermal process to establish bonds (e.g., covalent bonds) between the supporting structure 400A and the semiconductor dies 200 (e.g., at the interface of the supporting structure 400A and the semiconductor dies 200). The supporting structure 400A may be bonded to the semiconductor dies 200 by fusion bonding. In the case, an interface IF2 is between the supporting structure 400A and the semiconductor dies 200. The interface IF2 may be a fusion bonding interface (or a fusion bonding region). In some embodiments, the supporting structure 400A is thermally coupled to the semiconductor dies 200. In some embodiments, the supporting structure 400A is thermally coupled to and electrically isolated from the semiconductor dies 200. In the disclosure, the supporting structure 400A may also be referred to as a supporting carrier, a high performance carrier, or a high performance supporting structure.

For example, the supporting structure 400A is pre-fabricated. The supporting structure 400A may be a single-layer structure, such as in a form of bulk structure, as shown in FIG. 7. In some embodiments, the supporting structure 400A is made of a ceramic material, a semiconductor material, a polymer material, or a metallic material (such as metals or metal alloys). In some embodiments, the supporting structure 400A has a CTE approximately ranging from 2 ppm/K to 4 ppm/K. In a non-limiting example, the CTE of the supporting structure 400A may be about 2.0 ppm/K, 2.1 ppm/K, 2.2 ppm/K, 2.3 ppm/K, 2.4 ppm/K, 2.5 ppm/K, 2.6 ppm/K, 2.7 ppm/K, 2.8 ppm/K, 2.9 ppm/K, 3.0 ppm/K, 3.1 ppm/K, 3.2 ppm/K, 3.3 ppm/K, 3.4 ppm/K, 3.5 ppm/K, 3.6 ppm/K, 3.7 ppm/K, 3.8 ppm/K, 3.9 ppm/K, or 4.0 ppm/K, although other suitable CTE value may alternatively be utilized. Owing to the supporting structure 400A (having the CTE value closer to those of the semiconductor substrates 210 of the semiconductor dies 200), the warpage of the semiconductor device 1000A during the manufacture thereof can be suppressed.

In some embodiments, the supporting structure 400A has a Young's modulus (E) greater than 150 GPa. In a non-limiting example, the Young's modulus of the supporting structure 400A may be greater than 150 GPa and less than or substantially equal to 5000 GPa, greater than 150 GPa and less than or substantially equal to 4000 GPa, greater than 150 GPa and less than or substantially equal to 3000 GPa, greater than 150 GPa and less than or substantially equal to 2000 GPa, greater than 150 GPa and less than or substantially equal to 1000 GPa, greater than 150 GPa and less than or substantially equal to 900 GPa, greater than 150 GPa and less than or substantially equal to 800 GPa, greater than 150 GPa and less than or substantially equal to 700 GPa, greater than 150 GPa and less than or substantially equal to 600 GPa, greater than 150 GPa and less than or substantially equal to 500 GPa, greater than 150 GPa and less than or substantially equal to 400 GPa, greater than 150 GPa and less than or substantially equal to 300 GPa, although other suitable Young's modulus may alternatively be utilized. Owing to the supporting structure 400A (having the Young's modulus greater than those of the semiconductor substrates 210 of the semiconductor dies 200), the warpage of the semiconductor device 1000A can be suppressed during bonding the semiconductor device 1000A to an external component or element.

In some embodiments, the supporting structure 400A has a thermal conductivity greater than 150W/(m*K). In a non-limiting example, the thermal conductivity of the supporting structure 400A may be greater than greater than 150W/(m*K) and less than or substantially equal to 1000W/(m*K), greater than 150W/(m*K) and less than or substantially equal to 950W/(m*K), greater than 150W/(m*K) and less than or substantially equal to 900W/(m*K), greater than 150W/(m*K) and less than or substantially equal to 850W/(m*K), greater than 150W/(m*K) and less than or substantially equal to 800W/(m*K), greater than 150W/(m*K) and less than or substantially equal to 750W/(m*K), greater than 150W/(m*K) and less than or substantially equal to 700W/(m*K), greater than 150W/(m*K) and less than or substantially equal to 650W/(m*K), greater than 150W/(m*K) and less than or substantially equal to 600W/(m*K), greater than 150W/(m*K) and less than or substantially equal to 550W/(m*K), greater than 150W/(m*K) and less than or substantially equal to 500W/(m*K), greater than 150W/(m*K) and less than or substantially equal to 450W/(m*K), greater than 150W/(m*K) and less than or substantially equal to 400W/(m*K), greater than 150W/(m*K) and less than or substantially equal to 350W/(m*K), greater than 150W/(m*K) and less than or substantially equal to 300W/(m*K), greater than 150W/(m*K) and less than or substantially equal to 250W/(m*K), greater than 150W/(m*K) and less than or substantially equal to 200W/(m*K), although other suitable thermal conductivity may alternatively be utilized. Owing to the supporting structure 400A (having the thermal conductivity greater than those of the semiconductor substrates 210 of the semiconductor dies 200), the heat generated by the semiconductor dies 200 during the operation can be efficiently dissipating to the external environment through the supporting structure 400A.

A thickness T400A of the supporting structure 400A may be approximately ranging from 50 μm to 5 mm, although other suitable thickness may alternatively be utilized. For example, the thickness T400A of the supporting structure 400A is greater than or substantially equal to 50 μm and less than or substantially equal to 5 mm. In a non-limiting example, the thickness T400A of the supporting structure 400A may be greater than or substantially equal to 50 μm and less than or substantially equal to 4 mm. In another non-limiting example, the thickness T400A of the supporting structure 400A may be greater than or substantially equal to 50 μm and less than or substantially equal to 3 mm. In another non-limiting example, the thickness T400A of the supporting structure 400A may be greater than or substantially equal to 50 μm and less than or substantially equal to 2 mm. In another non-limiting example, the thickness T400A of the supporting structure 400A may be greater than or substantially equal to 50 μm and less than or substantially equal to 1 mm. In some embodiments, the shape and the size of the supporting structure 400A are similar or substantially identical to the shape and the size of the wafer W1 in the vertical projection along the direction Z. However, the disclosure is not limited thereto. In some embodiments, a material of the supporting structure 400A is different from a material of the semiconductor substrates 110 of the semiconductor dies 100. In some embodiments, a material of the supporting structure 400A is different from a material of the semiconductor substrates 210 of the semiconductor dies 200.

During the bonding process of the semiconductor dies 200 and the supporting structure 400A, bonds (e.g., covalent bonds) between the supporting structure 400A and the insulating encapsulation 300 (e.g., at the interface of the supporting structure 400A and the semiconductor dies 200) may be also established. That is, the supporting structure 400A is further bonded to the insulating encapsulation 300, for example.

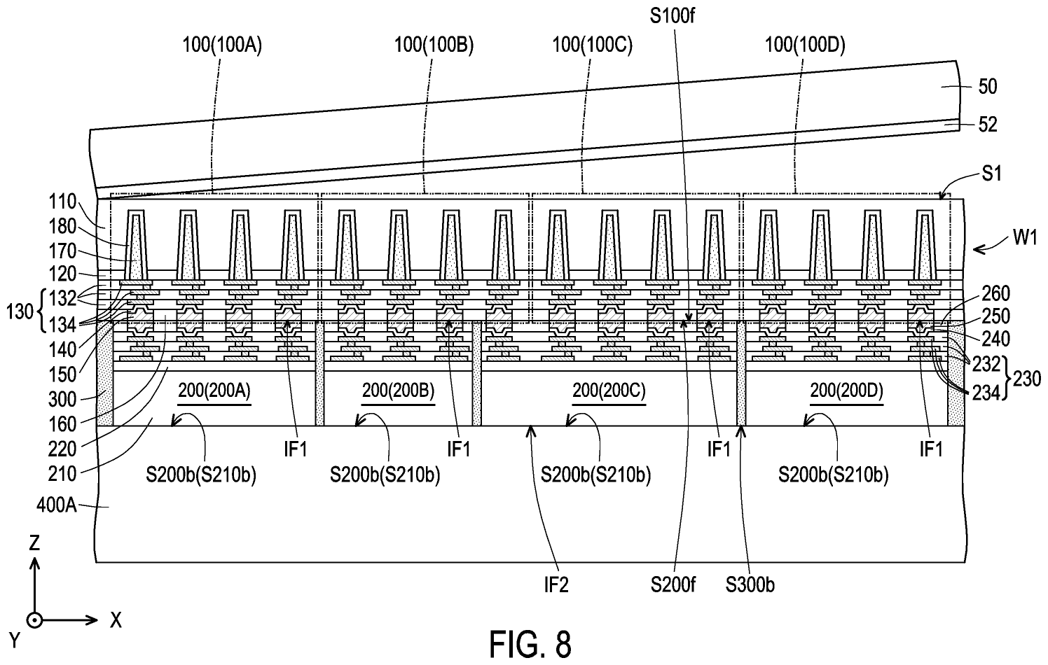

Referring to FIG. 7 and FIG. 8 together, in some embodiments, the whole structure depicted in FIG. 7 is flipped (turned upside down), the carrier 50 is detached from the wafer W1 through a debonding process, such that the wafer W1 (including the semiconductor dies 100) is separated from the carrier 50. The carrier 50 and the debond layer 52 are removed, as shown in FIG. 8, for example. In embodiments where the debond layer 52 is the LTHC release layer, an UV laser irradiation may be utilized to facilitate peeling of the wafer W1 (including the semiconductor dies 100) from the carrier 50. In certain embodiments, the wafer W1 (e.g., the bottom surfaces S1 of the semiconductor substrate 110 of the semiconductor dies 100) are accessibly exposed, as show in FIG. 8.

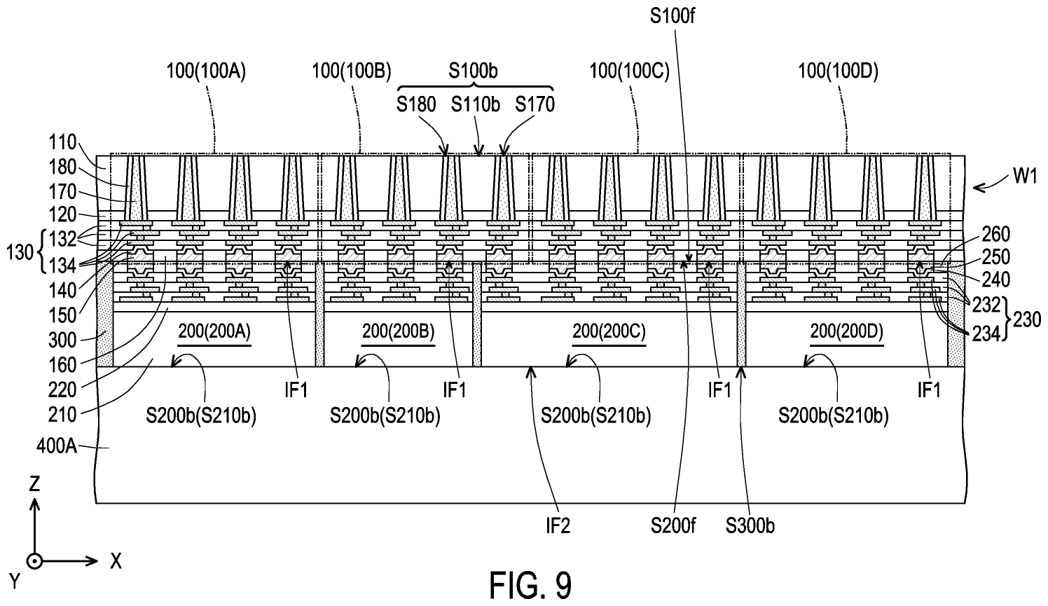

Referring to FIG. 9, in some embodiments, the wafer W1 is thinned down to expose the conductive pillars 170 of the semiconductor dies 100 (e.g., 100A, 100B, 100C, and 100D). The thinning process may be performed by a mechanical grinding process, a CMP process, an etching process, and/or combinations thereof. The etching process may include a dry etching, a wet etching, or a combination thereof. In some embodiments, during the thinning process of the wafer W1, the semiconductor substrate 110 and the liners 160 of each of the semiconductor dies 100 (e.g., 100A, 100B, 100C, and 100D) are planarized to accessibly reveal the conductive pillars 170 of the semiconductor dies 100 (e.g., 100A, 100B, 100C, and 100D). In some embodiments, portions of the conductive pillars 170 of the semiconductor dies 100 (e.g., 100A, 100B, 100C, and 100D) are slightly planarized as well. In some embodiments, after the planarization process, a cleaning step may be optionally performed to clean and remove the residue generated from the planarization process. However, the disclosure is not limited thereto, and the planarization process may be performed through any other suitable method.

For example, a surface S110b of the semiconductor substrate 110, surfaces S160 of the liners 160 and surfaces S170 of the conductive pillars 170 in each of the semiconductor dies 100 included in the wafer W1 are substantially level with each other. In some embodiments, the surface S110b of the semiconductor substrate 110, the surfaces S160 of the liners 160 and the surfaces S170 of the conductive pillars 170 of each of the semiconductor dies 100 included in the wafer W1 are substantially coplanar to each other. In the case, the surface S110b of the semiconductor substrate 110, the surfaces S160 of the liners 160 and the surfaces S170 of the conductive pillars 170 of each of the semiconductor dies 100 (e.g., 100A, 100B, 100C, and 100D) together constitute a back-side, rear-side, or non-active side S100b of each of the semiconductor dies 100, as shown in FIG. 9. In some embodiments, a back side of the wafer W1 is where the back-sides S100b of the semiconductor dies 100 located at. In the case, the conductive pillars 170 may be referred to as through semiconductor vias or through silicon vias (TSVs). For example, in the direction Z, the front sides S100f of the semiconductor dies 100 are opposite to the back sides S100b of the semiconductor dies 100.

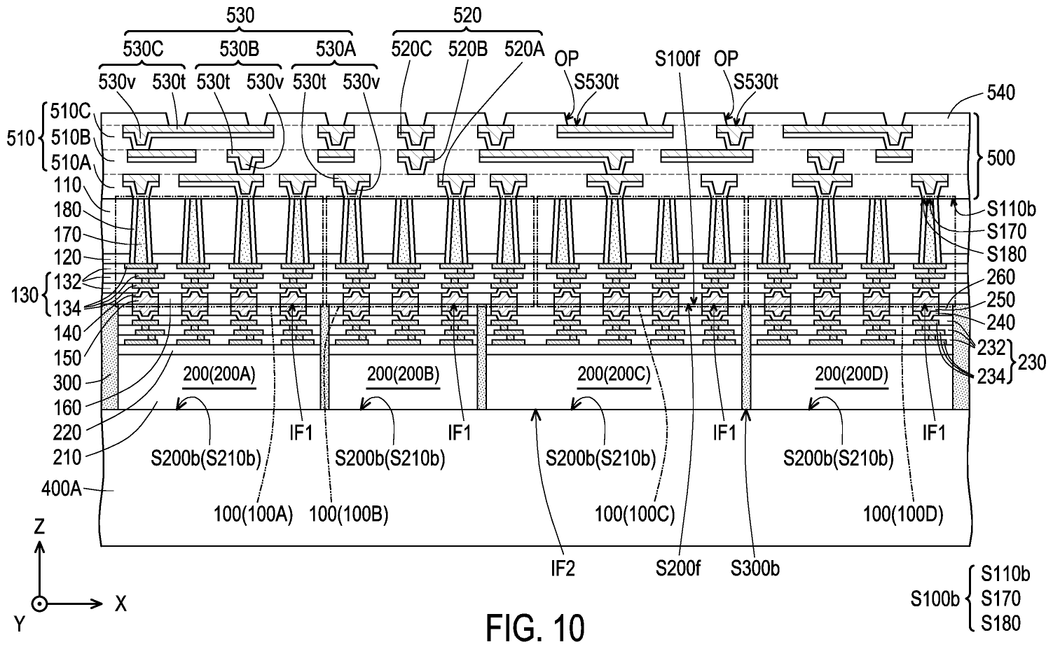

Referring to FIG. 10, in some embodiments, a redistribution circuit structure 500 is formed on the wafer W1 (including the semiconductor dies 100). For example, the redistribution circuit structure 500 is disposed on (e.g., in physical contact with) the back sides S100b of the semiconductor dies 100. As shown in FIG. 10, the redistribution circuit structure 500 may be electrically coupled to the semiconductor dies 100 by contacting the conductive pillars 170. In some embodiments, the redistribution circuit structure 500 includes one or more dielectric layers 510 (e.g., 510A, 510B and 510C), one or more seed layers 520 (e.g., 520A, 520B and 520C), one or more patterned conductive layers 530 (e.g., 530A, 530B and 530C), and a passivation layer 540. In some embodiments, each patterned conductive layer 530 includes a line portion 530t extending along a horizontal direction (e.g., the direction X or the direction Y), a via portion 530v extending along a vertical direction (e.g., the direction Z), and/or a combination thereof. One seed layer 520 and a respective one patterned conductive layer 530 overlying thereto may be collectively referred to as a metallization layer, a routing layer or a redistribution layer of the redistribution circuit structure 500 to provide routing functions. The dielectric layers 510 together may be referred to as a dielectric structure of the redistribution circuit structure 500, sometimes. In some embodiments, in the redistribution circuit structure 500, the dielectric layers (e.g., 510) and the metallization layers (e.g., 520 and 530) are arranged in alternation, and the passivation layer (e.g., 540) is disposed on a topmost layer (e.g., 510C) of the dielectric layers (e.g., 510) and a topmost layer (e.g., 530C) of the patterned conductive layers (e.g., 530). As shown in FIG. 10, for example, the passivation layer 540 includes a plurality of openings OP penetrating there-through and exposing surfaces S530t of portions of the topmost layer (e.g., 530C) of the patterned conductive layers 530 for external connection. In the disclosure, the numbers of layers of the dielectric layers 510, the seed layers 520, and the patterned conductive layers 530 are not limited to what is depicted in FIG. 10, may be selected and designated based on the demand and design layout.

In some embodiments, the redistribution circuit structure 500 may be formed by, but not limited to: forming a blanket layer of first dielectric material over the wafer W1; patterning the first dielectric material blanket layer to form the dielectric layer 510A having a plurality of first openings (not labeled) penetrating there-through and accessibly revealing the conductive pillars 170 of the semiconductor dies 100 exposed by the back sides S100b of the semiconductor dies 100; forming a blanket layer of first seed layer material over the dielectric layer 510A, the first seed layer material blanket layer extending into the first openings to line the first openings and in contact with the conductive pillars 170 of the semiconductor dies 100 exposed by the back sides S100b of the semiconductor dies 100; forming a blanket layer of a first conductive material over the first seed layer material blanket layer; patterning the first conductive material blanket layer to form the patterned conductive layer 530A; using the patterned conductive layer 530A as etching mask to pattern the first seed layer material blanket layer and form the seed layer 520A; forming a blanket layer of second dielectric layer over the patterned conductive layer 530A, the seed layer 520A and the dielectric layer 510A; patterning the second dielectric material blanket layer to form the dielectric layer 510B having a plurality of second openings (not labeled) there-through and accessibly revealing an illustrated top surface of the patterned conductive layer 530A; forming a blanket layer of second seed layer material over the dielectric layer 510B, the second seed layer material blanket layer extending into the second openings to line the second openings and in contact with the exposed patterned conductive layer 530A; forming a blanket layer of a second conductive material over the second seed layer material blanket layer; patterning the second conductive material blanket layer to form the patterned conductive layer 530B; using the patterned conductive layer second 530B as etching mask to pattern the second seed layer material blanket layer and form the seed layer 520B; forming a blanket layer of third dielectric layer over the patterned conductive layer 530B, the seed layer 520B and the dielectric layer 510B; patterning the third dielectric material blanket layer to form a dielectric layer 510C having a plurality of third openings (not labeled) penetrating there-through and accessibly revealing an illustrated top surface of the patterned conductive layer 530B; forming a blanket layer of third seed layer material over the dielectric layer 510C, the third seed layer material blanket layer extending into the third openings to line the third openings and in contact with the exposed patterned conductive layer 530B; forming a blanket layer of a third conductive material over the third seed layer material blanket layer; patterning the third conductive material blanket layer to form the patterned conductive layer 530C; using the patterned conductive layer 530C as etching mask to pattern the third seed layer material blanket layer and form the seed layer 520C; forming a blanket layer of fourth dielectric layer over the patterned conductive layer 530C, the seed layer 520C and the dielectric layer 510C; and patterning the fourth dielectric material blanket layer to form a passivation layer 540 having a plurality of openings OP penetrating there-through and accessibly revealing an illustrated top surface S530t of the patterned conductive layer 530C. Up to here, the redistribution circuit structure 500 is manufactured. The redistribution circuit structure 500 may be formed on the semiconductor dies 100 by single or dual damascene process. The disclosure is not limited thereto.

The material of each of the dielectric layers 510A, 510B, 510C and the passivation layer 540 may be PI, PBO, BCB, a nitride such as silicon nitride, an oxide such as silicon oxide, PSG, BSG, BPS G, a combination thereof or the like, which may be patterned using a photolithography and/or etching process. The first, second, third, and/or fourth dielectric material blanket layer may be formed by suitable fabrication techniques such as spin-on coating, CVD (e.g., PECVD), or the like. In some embodiments, the materials of the dielectric layers 510A, 510B, 510C and the passivation layer 540 are the same to each other. Alternatively, the materials of the dielectric layers 510A, 510B, 510C and the passivation layer 540 may be different, in part or all.

The seed layers 520A, 520B and 520C individually are referred to as a metal layer, which can be a single layer or a composite layer including a plurality of sub-layers formed of different materials. For example, the seed layers 520A, 520B and 520C each may be or include a titanium layer and a copper layer over the titanium layer. The first, second, and/or third seed layer material blanket layers may be formed in a manner of a blanket layer made of metal or metal alloy materials, the disclosure is not limited thereto. The material of each of the first, second, and/or third seed layer material blanket layers may include titanium, copper, molybdenum, tungsten, titanium nitride, titanium tungsten, combinations thereof, or the like, which may be formed using, for example, sputtering, physical vapor deposition (PVD), or the like. The first, second, and/or third seed layer material blanket layers may be patterned by etching, such as a dry etching process, a wet etching process, or a combination thereof; the disclosure is not limited thereto. In some embodiments, the materials of the seed layers 520A, 520B and 520C are the same to each other. Alternatively, the materials of the seed layers 520A, 520B and 520C may be different, in part or all.

The material of each of the first, second, and/or third conductive material blanket layers for forming the patterned conductive layers 530A, 530B and 530C may be made of conductive materials formed by electroplating or deposition, such as copper, copper alloy, aluminum, aluminum alloy, or combinations thereof, which may be patterned to form a plurality of conductive patterns/segments using a photolithography and etching process. In some embodiments, the conductive patterns/segments each include the line portion 530t extending along a horizontal direction (e.g., the direction X and/or Y) and/or the line portion 530v extending along a horizontal direction (e.g., the direction X and/or Y) in addition to the via portion 530v connecting to the line portion 530t and extending along a vertical direction (e.g., the direction Z). In one embodiment, the materials of the patterned conductive layers 530A, 530B and 530C are the same to each other. Alternatively, the materials of the patterned conductive layers 530A, 530B and 530C may be different, in part or all.

As shown in FIG. 10, the redistribution circuit structure 500 is electrically connected to the semiconductor dies 100 through the conductive pillars 170, for example. In some embodiments, the redistribution circuit structure 500 is electrically connected to the semiconductor dies 200 through the semiconductor dies 100. In addition, one metallization layer (e.g., 520A and 530A) and the dielectric layer (e.g., 510A) laterally covering the one metallization layer is considered as a first build-up layer of the redistribution circuit structure 500, one metallization layer (e.g., 520B and 530B) and the dielectric layer (e.g., 510B) laterally covering the other one metallization layer is considered as a second build-up layer of the redistribution circuit structure 500, and other one metallization layer (e.g., 520C and 530C) and the dielectric layer (e.g., 510C) laterally covering the other one metallization layer is considered as a third build-up layer of the redistribution circuit structure 500. The number of the build-up layers of the redistribution circuit structure 500 may be selected and designated based on demand and design layout, and is not limited thereto. The redistribution circuit structure 500 may be referred to as a routing structure, a routing circuit structure, a redistribution structure, or a circuit structure.

Referring to FIG. 11, in some embodiments, a plurality of under-ball metallurgy (UBM) patterns 600 and a plurality of conductive terminals 700 are sequentially formed over the redistribution circuit structure 500. In some embodiments, the UBM patterns 600 each are located between a respective one of the conductive terminals 700 and the passivation layer 540 of the redistribution circuit structure 500. For example, the UBM patterns 600 are disposed on the passivation layer 540 and further extend into the openings OP formed in the passivation layer 540 to be in (physical) contact with the patterned conductive layer 530C exposed therefrom so to be electrically connected to the patterned conductive layer 530C, and the conductive terminals 700 are disposed on (e.g., in physical contact with) and electrically connected to the UBM patterns 600. Due to the UBM patterns 600, the adhesion strength between the conductive terminals 700 and the passivation layer 540 of the redistribution circuit structure 500 is enhanced.

In some embodiments, the UBM patterns 600 are physically connected to and electrically connected to the redistribution circuit structure 500. In some embodiments, the conductive terminals 700 are electrically coupled to the redistribution circuit structure 500 through the UBM patterns 600. In some embodiments, the conductive terminals 700 are electrically coupled to the wafer W1 through the UBM patterns 600 and the redistribution circuit structure 500. In some embodiments, some of the conductive terminals 700 are electrically coupled to the semiconductor die 100A through some of the UBM patterns 600 and the redistribution circuit structure 500. In some embodiments, some of the conductive terminals 700 are electrically coupled to the semiconductor die 100B through some of the UBM patterns 600 and the redistribution circuit structure 500. In some embodiments, some of the conductive terminals 700 are electrically coupled to the semiconductor die 100C through some of the UBM patterns 600 and the redistribution circuit structure 500. In some embodiments, some of the conductive terminals 700 are electrically coupled to the semiconductor die 100D through some of the UBM patterns 600 and the redistribution circuit structure 500. In some embodiments, some of the conductive terminals 700 are electrically coupled to the semiconductor die 200A through some of the UBM patterns 600, the redistribution circuit structure 500 and the semiconductor die 100A. In some embodiments, some of the conductive terminals 700 are electrically coupled to the semiconductor die 200B through some of the UBM patterns 600, the redistribution circuit structure 500 and the semiconductor die 100B. In some embodiments, some of the conductive terminals 700 are electrically coupled to the semiconductor die 200C through some of the UBM patterns 600, the redistribution circuit structure 500 and the semiconductor dies 100B, 100C. In some embodiments, some of the conductive terminals 700 are electrically coupled to the semiconductor die 200D through some of the UBM patterns 600, the redistribution circuit structure 500 and the semiconductor die 100D.

In some embodiments, the UBM patterns 600 are made of a metal layer including a single layer or a metallization layer including a composite layer with a plurality of sub-layers formed of different materials. In some embodiments, the UBM patterns 600 include copper, nickel, molybdenum, titanium, tungsten, titanium nitride, titanium tungsten, combinations thereof, or the like. The UBM patterns 600 may include a titanium layer and a copper layer over the titanium layer. The UBM patterns 600 may be formed using electroplating, sputtering, PVD, or the like. For example, the UBM patterns 600 are conformally formed on the passivation layer 540 by sputtering to extend on an outermost surface of the passivation layer 540 and further extend into the openings OP formed in the passivation layer 540 and thus are in physical contact with the surface S530t of the patterned conductive layer 530C exposed by the openings OP formed in the passivation layer 540. The UBM patterns 600 are electrically isolated from one another. The number of the UBM patterns 600 may not be limited in this disclosure, and may correspond to the number of the portions of the patterned conductive layer 530C exposed by the openings OP formed in the passivation layer 540.

In some embodiments, the conductive terminals 700 are physically connected to and electrically connected to the UBM patterns 600, and are electrically coupled to the redistribution circuit structure 500 through the UBM patterns 600. In some embodiments, the conductive terminals 700 are disposed on the UBM patterns 600 by ball placement process or reflow process. For example, the conductive terminals 700 includes micro-bumps, metal pillars, ENEPIG formed bumps, C4 bumps (for example, which may have, but not limited to, a size of about 80 μm), a BGA bumps or balls (for example, which may have, but not limited to, a size of about 400 μm), solder balls, or the like. The disclosure is not limited thereto. The number of the conductive terminals 700 is not limited to the drawings of the embodiments, and may be selected and designated based on the demand and design layout. The number of the conductive terminals 700 may be controlled by adjusting the number of the UBM patterns 600. When solder is used, the solder may include either eutectic solder or non-eutectic solder. The solder may include lead or be lead-free, and may include Sn—Ag, Sn—Cu, Sn—Ag—Cu, or the like. The conductive terminals 700 may be solder free. The conductive terminals 700 may be referred to as conductors, input/output (I/O) terminals, conductive connectors, or conductive I/O terminals of the semiconductor device 1000A for electrical connection with the external component or element (e.g., an additional semiconductor package/device, a circuit substrate, an interposer, an capacitor, a power source, or the like, etc.).

However, the disclosure is not limited thereto. In some alternative embodiments, the UBM patterns 600 may be omitted. In such alternative embodiments, the conductive terminals 700 may be directly connected to (e.g., in physical contact with) the redistribution circuit structure 500 (e.g., the portions of the patterned conductive layer 530C exposed by the openings OP). In further alternative embodiments, the conductive terminals 700 may be omitted.

In some embodiments, after forming the conductive terminals 700, a dicing (or singulation) process is sequentially performed to cut through the redistribution circuit structure 500, the wafer W1, the insulating encapsulation 300, and the supporting structure 400 so to form individual and separated semiconductor devices 1000A. Up to here, the semiconductor device 1000A is manufactured. In some embodiments, a sidewall of the semiconductor device 1000A includes a sidewall SW500 of the redistribution circuit structure 500, a sidewall SW100 of the semiconductor dies 100 (being connected to each other), a sidewall SW300 of the insulating encapsulation 300, and a sidewall SW400A of the supporting structure 400A. For example, as shown in FIG. 11, the sidewall SW500 of the redistribution circuit structure 500, the sidewall SW100 of the semiconductor dies 100 (being connected to each other), the sidewall SW300 of the insulating encapsulation 300, and the sidewall SW400A of the supporting structure 400A are substantially aligned with each other. The first tier T1 and the second tier T2 bonded thereto together may be considered as a die stack or a stacking structure of dies, in the disclosure. In some embodiments, the semiconductor device 1000A includes a supporting structure 400A, a die stack (including the first tier T1 and the second tier T2) disposed on the supporting structure 400A, the redistribution circuit structure 500 disposed on the die stack and the conductive terminals 700 disposed over the redistribution circuit structure 500 through the UBM patterns 600, where the die stack is between the redistribution circuit structure 500 and the supporting structure 400A, and the redistribution circuit structure 500 is between the die stack and the conductive terminals 700.

In addition, on the X-Y plane, a projection area of a positioning location of each semiconductor die included in the second tier T2 independently may be less than, greater than or substantially equal to a projection area of a positioning location of a respectively one semiconductor die included in the first tier T1 overlapped therewith in the direction Z. For the semiconductor device 1000A in FIG. 11, on the X-Y plane, a projection area of a positioning location of one semiconductor die (e.g., 100A, 100D) included in the second tier T2 may be substantially equal to a projection area of a positioning location of one semiconductor die (e.g., 200A, 200D) included in the first tier T1. For the semiconductor device 1000A in FIG. 11, on the X-Y plane, a projection area of a positioning location of one semiconductor die (e.g., 100B) included in the second tier T2 may be greater than a projection area of a positioning location of one semiconductor die (e.g., 200B) included in the first tier T1. For the semiconductor device 1000A in FIG. 11, on the X-Y plane, a projection area of a positioning location of one semiconductor die (e.g., 100C) included in the second tier T2 may be less than a projection area of a positioning location of one semiconductor die (e.g., 200C) included in the first tier T1.

The disclosure is not limited thereto. In one non-limiting example, on the X-Y plane, a projection area of a positioning location of each semiconductor die included in the second tier T2 all may be less than a projection area of a positioning location of a respectively one semiconductor die included in the first tier T1 overlapped therewith in the direction Z. Alternatively, on the X-Y plane, a projection area of a positioning location of each semiconductor die included in the second tier T2 all may be greater than a projection area of a positioning location of a respectively one semiconductor die included in the first tier T1 overlapped therewith in the direction Z. Or alternatively, on the X-Y plane, a projection area of a positioning location of each semiconductor die included in the second tier T2 all may be substantially equal to a projection area of a positioning location of a respectively one semiconductor die included in the first tier T1 overlapped therewith in the direction Z. In one non-limiting example, on the X-Y plane, a projection area of a positioning location of each semiconductor die included in the second tier T2 independently may be less than or substantially equal to a projection area of a positioning location of a respectively one semiconductor die included in the first tier T1 overlapped therewith in the direction Z. Alternatively, on the X-Y plane, a projection area of a positioning location of each semiconductor die included in the second tier T2 independently may be greater than or substantially equal to a projection area of a positioning location of a respectively one semiconductor die included in the first tier T1 overlapped therewith in the direction Z. Or alternatively, on the X-Y plane, a projection area of a positioning location of each semiconductor die included in the second tier T2 independently may be less than or greater than a projection area of a positioning location of a respectively one semiconductor die included in the first tier T1 overlapped therewith in the direction Z.

In one embodiment, the dicing process is a wafer dicing process including mechanical blade sawing or laser cutting. The disclosure is not limited thereto. Before the dicing (or singulation) process, for example, the structure depicted in FIG. 10 is flipped, and a holding device (not shown) is adopted to secure the structure depicted in FIG. 10 by holding the conductive terminals 700. For example, the holding device may be an adhesive tape, a carrier film, or a suction pad. In some embodiments, after the dicing (or singulation) process, the conductive terminals 700 are released from the holding device.

As illustrated in FIG. 11, the semiconductor device 1000A includes the supporting structure 400A, a first tier T1 of (semiconductor) dies (such as the semiconductor dies 200 laterally encapsulated by the insulating encapsulation 300), a second tier T2 of (semiconductor) dies (such as the semiconductor dies 100 interconnected thereto), the redistribution circuit structure 500, the UBM patterns 600, and the conductive terminals 700, in some embodiments. For example, in the semiconductor device 1000A, the semiconductor dies 200 included in the first tier T1 are laterally spacing from each other through the insulating encapsulation 300, and the semiconductor dies 100 included in the second tier T2 are physically connected to each other in the lateral direction (e.g., the direction X and/or the direction Y). In the embodiments of the semiconductor device 1000A, the semiconductor dies 200 included in the first tier T1 are bonded to the semiconductor dies 100 included in the second tier T2 through a chip-on-wafer bonding process.

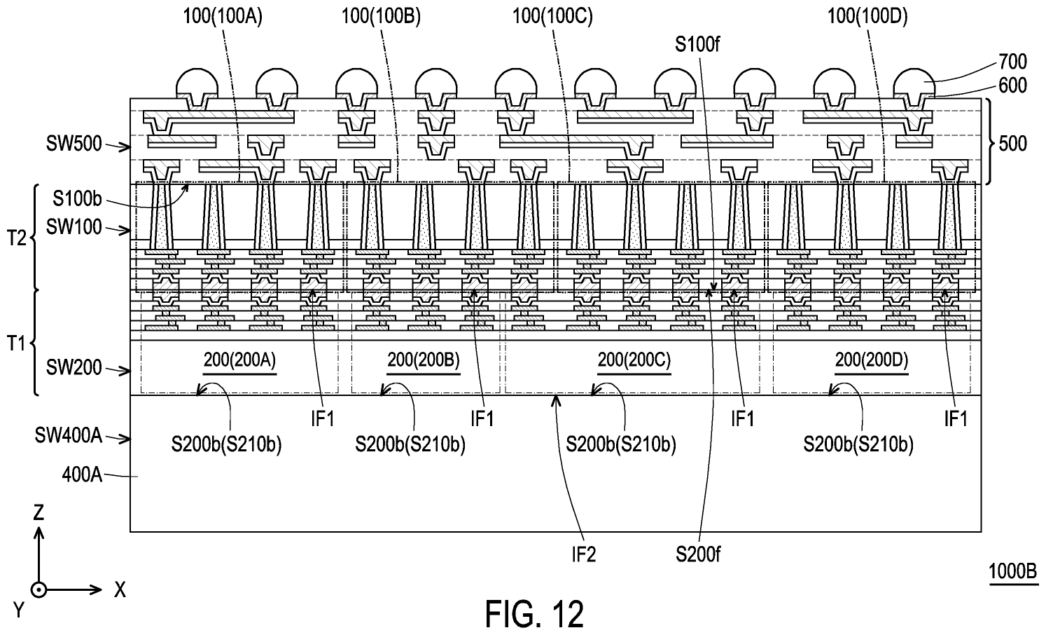

However, the disclosure is not limited thereto; in some alternative embodiments, the semiconductor dies 200 included in the first tier Ti are bonded to the semiconductor dies 100 included in the second tier T2 through a wafer-on-wafer bonding process, see FIG. 12. FIG. 12 is a schematic cross-sectional view showing a semiconductor device 1000B in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein.

For example, the semiconductor device 1000B of FIG. 12 and the semiconductor device 1000A of FIG. 11 are similar; and the difference is that, in the semiconductor device 1000B depicted in FIG. 12, the semiconductor dies 200 included in the first tier T1 are physically connected to each other in the lateral direction (e.g., the direction X and/or the direction Y), and the insulating encapsulation 300 are omitted. In some embodiments, a sidewall of the semiconductor device 1000B includes a sidewall SW500 of the redistribution circuit structure 500, a sidewall SW100 of the semiconductor dies 100 (being connected to each other), a sidewall SW200 of the semiconductor dies 200 (being connected to each other), and a sidewall SW400A of the supporting structure 400A. For example, as shown in FIG. 12, the sidewall SW500 of the redistribution circuit structure 500, the sidewall SW100 of the semiconductor dies 100 (being connected to each other), the sidewall SW200 of the semiconductor dies 200 (being connected to each other), and the sidewall SW400A of the supporting structure 400A are substantially aligned with each other.

The semiconductor device 1000B may be formed by, but not limited to, providing a wafer W1 including a plurality of semiconductor dies 100 (e.g., over the carrier 50) (similar to the processes of FIG. 1 and FIG. 4); providing and placing a wafer W2 including a plurality of semiconductor dies 200 over the wafer W1 (e.g., in a face-to-face configuration) (similar to the processes of FIG. 2 and FIG. 4); bonding the wafer W2 to the wafer W1 (e.g., through a wafer-on-wafer bonding process) (similar to the process of FIG. 4), where the semiconductor dies 200 are physically connected to and electrically coupled (and communicated) to the semiconductor dies 100, respectively; thinning the wafer W2 (similar to the process of FIG. 6); bonding a supporting structure 400A onto the back side of the wafer W2 (similar to the process of FIG. 7); revealing the back of the wafer W1 (e.g., by debonding the carrier 50) (similar to the process of FIG. 8); thinning the wafer W1 until TSVs (e.g., 170) of the semiconductor dies 100 being accessibly revealed (similar to the process of FIG. 9); forming a redistribution circuit structure 500 over the wafer W1 (similar to the process of FIG. 10), the redistribution circuit structure 500 being electrically coupled to the semiconductor dies 100 though the TSVs (e.g., 170); optionally forming UBM patterns 600 over the redistribution circuit structure 500 and electrically connected thereto (similar to the process of FIG. 11); optionally forming conductive terminals 700 over the UBM patterns 600 and electrically connected thereto (similar to the process of FIG. 11); and performing a dicing (or singulation) process to cut through the redistribution circuit structure 500, the wafer W1, the wafer W2 and the supporting structure 400A (similar to the process of FIG. 11).

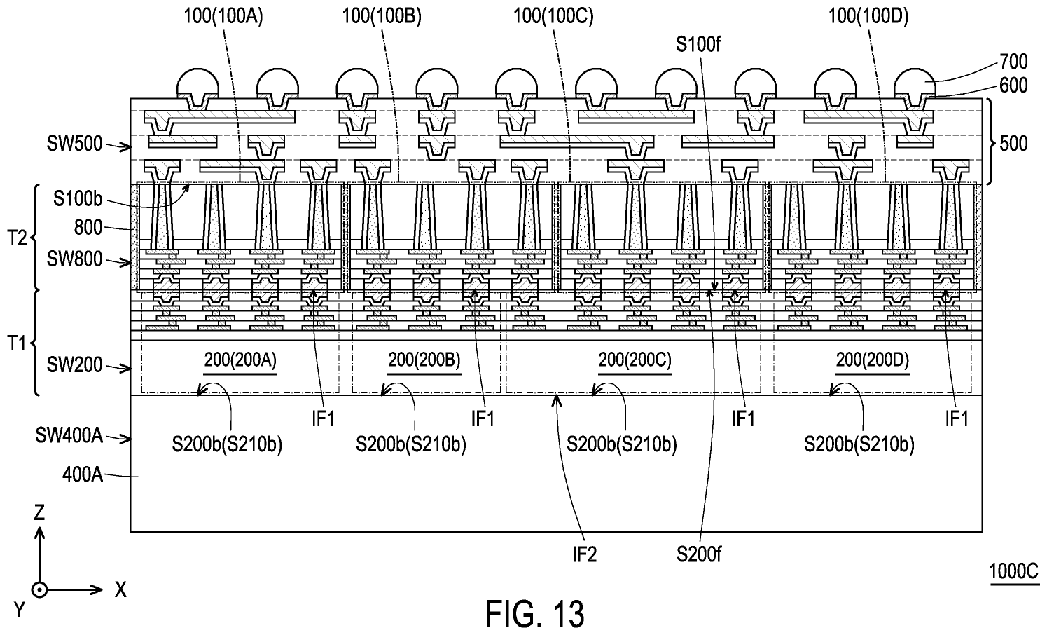

In other alternative embodiments, the semiconductor dies 200 included in the first tier T1 are bonded to the semiconductor dies 100 included in the second tier T2 through a wafer-on-chip bonding process, see FIG. 13. FIG. 13 is a schematic cross-sectional view showing a semiconductor device 1000C in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein.

For example, the semiconductor device 1000C of FIG. 13 and the semiconductor device 1000A of FIG. 11 are similar; and the difference is that, in the semiconductor device 1000C depicted in FIG. 13, the semiconductor dies 200 included in the first tier T1 are physically connected to each other in the lateral direction (e.g., the direction X and/or the direction Y) and the insulating encapsulation 300 are omitted, while the semiconductor dies 100 included in the second tier T2 are laterally spacing from each other through an insulating encapsulation 800. In some embodiments, a sidewall of the semiconductor device 1000C includes a sidewall SW500 of the redistribution circuit structure 500, a sidewall SW800 of the insulating encapsulation 800 of the second tier T2, a sidewall SW200 of the semiconductor dies 200 (being connected to each other), and a sidewall SW400A of the supporting structure 400A. For example, as shown in FIG. 13, the sidewall SW500 of the redistribution circuit structure 500, the sidewall SW800 of the insulating encapsulation 800, the sidewall SW200 of the semiconductor dies 200 (being connected to each other), and the sidewall SW400A of the supporting structure 400A are substantially aligned with each other.

The semiconductor device 1000C may be formed by, but not limited to, providing a wafer W1 including a plurality of semiconductor dies 100 (similar to the process of FIG. 1); dicing the wafer W1 to form individual and separated semiconductor dies 100 (similar to the process of FIG. 3); placing the semiconductor dies 100 over the carrier 50 (similar to the process of FIG. 4); laterally encapsulating the semiconductor dies 100 in the insulating encapsulation 800 to form the second tier T2 (similar to the processes of FIG. 5 and FIG. 6); providing and placing a wafer W2 including a plurality of semiconductor dies 200 over the semiconductor dies 100 in the second tier T2 (e.g., in a face-to-face configuration) (similar to the processes of FIG. 2 and FIG. 4); bonding the wafer W2 to the semiconductor dies 100 (e.g., through a wafer-on-chip bonding process) (similar to the process of FIG. 4), where the semiconductor dies 200 are physically connected to and electrically coupled (and communicated) to the semiconductor dies 100, respectively; thinning the wafer W2 (similar to the process of FIG. 6); bonding a supporting structure 400A onto the back side of the wafer W2 (see to the process of FIG. 7); revealing the bottom surfaces S1 of the semiconductor dies 100 in the second tier T2 (e.g., by debonding the carrier 50) (similar to the process of FIG. 8); thinning the semiconductor dies 100 in the second tier T2 until TSVs (e.g., 170) of the semiconductor dies 100 being accessibly revealed (similar to the process of FIG. 9); forming a redistribution circuit structure 500 over the semiconductor dies 100 in the second tier T2 (similar to the process of FIG. 10), the redistribution circuit structure 500 being electrically coupled to the semiconductor dies 100 though the TSVs (e.g., 170); optionally forming UBM patterns 600 over the redistribution circuit structure 500 and electrically connected thereto (similar to the process of FIG. 11); optionally forming conductive terminals 700 over the UBM patterns 600 and electrically connected thereto (similar to the process of FIG. 11); and performing a dicing (or singulation) process to cut through the redistribution circuit structure 500, the insulating encapsulation 800 of the second tier T2, the wafer W2 and the supporting structure 400A (similar to the process of FIG. 11). The formation and material of the insulating encapsulation 800 are similar to the forming process and material of the insulating encapsulation 300 as described in FIG. 5 and FIG. 6, and thus are not repeated herein for brevity.

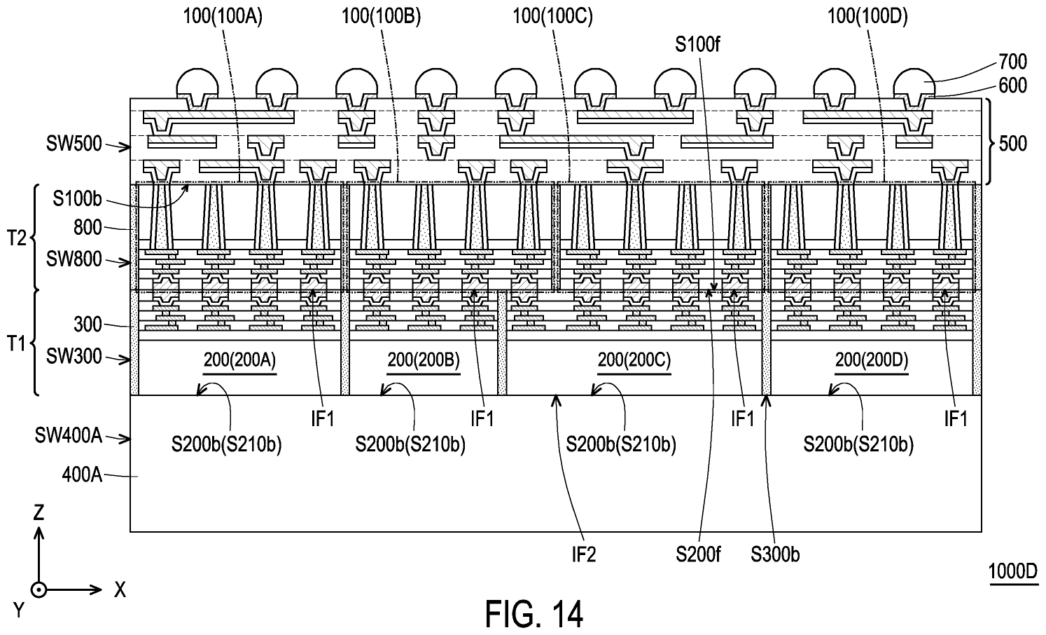

In further alternative embodiments, the semiconductor dies 200 included in the first tier T1 are bonded to the semiconductor dies 100 included in the second tier T2 through a chip-on-chip bonding process, see FIG. 14. FIG. 14 is a schematic cross-sectional view showing a semiconductor device 1000D in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein.

For example, the semiconductor device 1000D of FIG. 14 and the semiconductor device 1000A of FIG. 11 are similar; and the difference is that, in the semiconductor device 1000D depicted in FIG. 14, the semiconductor dies 100 included in the second tier T2 are also laterally spacing from each other, e.g., through an insulating encapsulation 800. In some embodiments, a sidewall of the semiconductor device 1000D includes a sidewall SW500 of the redistribution circuit structure 500, a sidewall SW800 of the insulating encapsulation 800, a sidewall SW300 of the insulating encapsulation 300 of the first tier T1, and a sidewall SW400A of the supporting structure 400A. For example, as shown in FIG. 14, the sidewall SW500 of the redistribution circuit structure 500, the sidewall SW800 of the insulating encapsulation 800, the sidewall SW300 of the insulating encapsulation 300, and the sidewall SW400A of the supporting structure 400A are substantially aligned with each other.

The semiconductor device 1000D may be formed by, but not limited to, providing a wafer W1 including a plurality of semiconductor dies 100 (similar to the process of FIG. 1); dicing the wafer W1 to form individual and separated semiconductor dies 100 (similar to the process of FIG. 3); placing the semiconductor dies 100 over the carrier 50 (similar to the process of FIG. 4); laterally encapsulating the semiconductor dies 100 in the insulating encapsulation 800 to form the second tier T2 (similar to the processes of FIG. 5 and FIG. 6); providing a wafer W2 including a plurality of semiconductor dies 200 (similar to the process of FIG. 2); dicing the wafer W2 to form individual and separated semiconductor dies 200 (similar to the process of FIG. 3); placing the semiconductor dies 200 over the semiconductor dies 100 in the second tier T2 (e.g., in a face-to-face configuration) (similar to the process of FIG. 4); bonding the semiconductor dies 200 to the semiconductor dies 100 (e.g., through a chip-on-chip bonding process) (similar to the process of FIG. 4), where the semiconductor dies 200 are physically connected to and electrically coupled (and communicated) to the semiconductor dies 100, respectively; laterally encapsulating the semiconductor dies 200 in the insulating encapsulation 300 to form the first tier T1 (similar to the processes of FIG. 5 and FIG. 6); thinning the semiconductor dies 200 in the first tier T1 (similar to the process of FIG. 6); bonding a supporting structure 400A onto the back sides of the semiconductor dies 200 in the first tier T1 (similar to the process of FIG. 7); revealing the bottom surface S1 of the semiconductor dies 100 in the second tier T2 (e.g., by debonding the carrier 50) (similar to the process of FIG. 8); thinning the semiconductor dies 100 in the second tier T2 until TSVs (e.g., 170) of the semiconductor dies 100 being accessibly revealed (similar to the process of FIG. 9); forming a redistribution circuit structure 500 over the semiconductor dies 100 in the second tier T2 (similar to the process of FIG. 10), the redistribution circuit structure 500 being electrically coupled to the semiconductor dies 100 though the TSVs (e.g., 170); optionally forming UBM patterns 600 over the redistribution circuit structure 500 and electrically connected thereto (similar to the process of FIG. 11); optionally forming conductive terminals 700 over the UBM patterns 600 and electrically connected thereto (similar to the process of FIG. 11); and performing a dicing (or singulation) process to cut through the redistribution circuit structure 500, the insulating encapsulation 800 in the second tier T2, the insulating encapsulation 300 in the first tier T1 and the supporting structure 400A (similar to the process of FIG. 11). The formation and material of the insulating encapsulation 800 are similar to the forming process and material of the insulating encapsulation 300 as described in FIG. 5 and FIG. 6, and thus are not repeated herein for brevity.

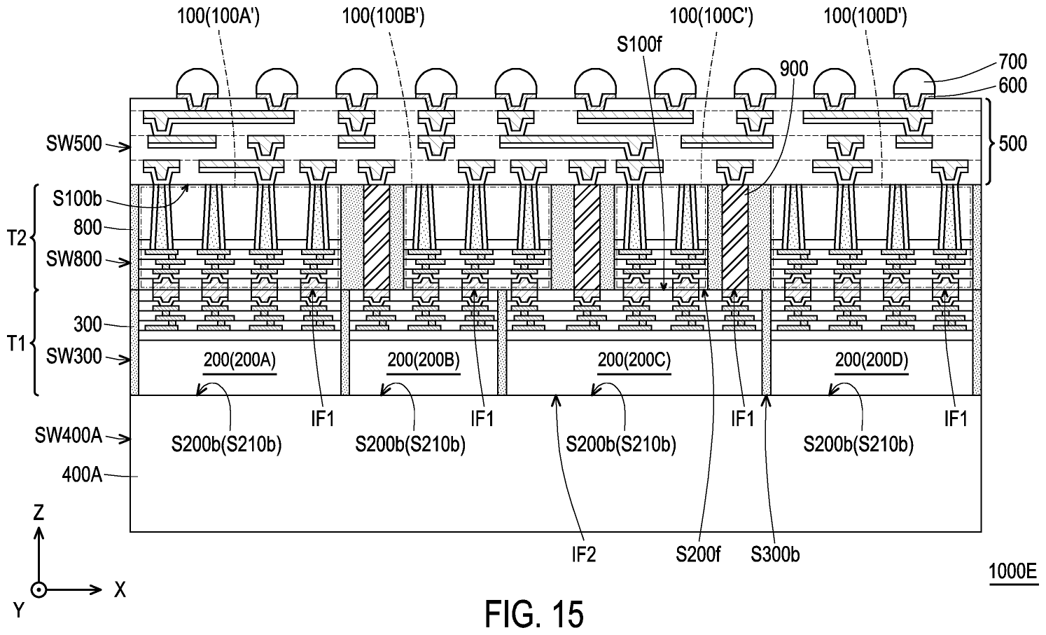

In above embodiments of the semiconductor devices 1000A, 1000B, 1000C and 1000D, there is no conductive pillars presented in and penetrating through the second tier T2 to electrically connect the redistribution circuit structure 500 and at least one of semiconductor dies 200 in the first tier T1. However, the disclosure is not limited thereto. In some alternative embodiments, one or more conductive pillars are included in the second tier T2 to provide additional electrical connections between the redistribution circuit structure 500 and at least one of semiconductor dies 200 in the first tier T1, see FIG. 15. FIG. 15 is a schematic cross-sectional view showing a semiconductor device 1000E in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein. For example, the semiconductor device 1000E of FIG. 15 and the semiconductor device 1000D of FIG. 14 are similar; and the difference is that, in the semiconductor device 1000E depicted in FIG. 15, a plurality of conductive pillars 900 are further provided in the second tier T2, where the conductive pillars 900 are laterally arranged next to the semiconductor dies 100 (e.g., semiconductor dies 100A, 100B′, 1000C′, 1000D) in the second tier T2 and penetrating through the insulating encapsulation 800 to electrically connect the semiconductor dies 200 in the first tier T1 and the redistribution circuit structure 500. The conductive pillars 900 may be referred to as through-insulator-vias (TIVs). The conductive pillars 900 may be referred to as vertical connections or vertical conductors. It is appreciated that, owing to the conductive pillars 900, one or more of the semiconductor dies 100 laterally next to the conductive pillars 900 (e.g., both located in the same tier) may be substituted with one or more of the semiconductor dies 200 or exclude the conductive pillars 170 and the liners 180, as long as the vertical electrical connections among the tiers of the die stack and electrical connections between the die stack and the redistribution circuit structure 500 are properly established.

As illustrated in FIG. 15, in some embodiments, the conductive pillars 900 stand on (e.g., in direct contact with) the front sides S200f of the semiconductor dies 200, where the conductive pillars 900 are physically connected to the bottommost layer (e.g., 530A and 520A) of the metallization layers (e.g., 530 and 520) of the redistribution circuit structure 500 exposed by the lowest layer (e.g., 510A) of the dielectric layers (e.g., 510) of the redistribution circuit structure 500 and the connecting vias 250 of the semiconductor dies 200 in the first tier T1. For simplification, only three conductive pillars 900 are presented in FIG. 15 for illustrative purposes, however, it should be noted that one or more conductive pillars 900 may be formed; the disclosure is not limited thereto. The number of the conductive pillars 900 can be selected and designated based on the demand and design layout, and is not limited thereto. A material of the conductive pillars 900 may include a metal material such as copper or copper alloys, or the like. For example, the conductive pillars 900 include copper posts or other metallic posts.

The formation of the semiconductor device 1000E of FIG. 15 is similar to the formation of semiconductor device 1000D of FIG. 14, except that in the formation of the semiconductor device 100E of FIG. 15, the forming process of the conductive pillars 900 are further included prior to encapsulate the semiconductor dies 100 by the insulating encapsulation 800. The conductive pillars 900 may be formed over the carrier 50 prior to the placement of the semiconductor dies 100 over the carrier 50 and prior to laterally encapsulating the semiconductor dies 100 in the insulating encapsulation 800. Or, the conductive pillars 900 may be formed over the carrier 50 prior to laterally encapsulating the semiconductor dies 100 in the insulating encapsulation 800 and after the placement of the semiconductor dies 100 over the carrier 50.

In embodiments where the conductive pillars 900 may be formed over the carrier 50 prior to the placement of the semiconductor dies 100 over the carrier 50 and prior to laterally encapsulating the semiconductor dies 100 in the insulating encapsulation 800, the formation of the conductive pillars 900 may include, but not limited to, forming a photo resist (not shown) on the debond layer 52 and over the carrier 50; patterning the photo resist to form a plurality of openings (not shown) penetrating the photo resist and exposing at least portions of debond layer 52 over the carrier 50 corresponding to (e.g., overlapped with) predetermined locations of the conductive pillars 900; forming a conductive material (not shown) in the openings to form the conductive pillars 900 (e.g., by deposition, plating (such as electroplating or electroless plating), or the like) on the debond layer 52 over the carrier 50; and removing the patterned photo resist (e.g., by acceptable ashing process and/or photoresist stripping process (such as using an oxygen plasma or the like)). A seed layer (not shown) may be further formed prior to forming the photo resist and is exposed by the openings of the patterned photo resist to facilitate the formation of the conductive material in the openings of the patterned photo resist, where the seed layer is patterned using the conductive material formed thereon as an etching mask, and the patterned seed layer and the conductive material formed thereon together considered as the conductive pillars 900. The formation and material of the seed layer is similar to or identical to the seed layers 520 as described in FIG. 10, and thus are not repeated herein for brevity.

The photo resist may be formed by spin coating or the like, and may be exposed to light for patterning. In some embodiments, a material of the photo resist includes a positive resist material or a negative resist material, that is suitable for a patterning process such as a photolithography process with a mask or a mask-less photolithography process (such as an electron-beam (e-beam) writing or an ion-beam writing). In the disclosure, the photo resist may be referred to as a photoresist layer or a resist layer. In some embodiments, the pattern of the photo resist is corresponding to the positioning locations of the conductive pillars 900. In alternative embodiments, the conductive pillars 900 may be pre-fabricated structures through other processes and are mounted over the debond layer 52 over the carrier 50 by any suitable method, after or before the semiconductor dies 100 are placed on the debond layer 520.

However, the disclosure is not limited thereto. In alternative embodiments, the semiconductor device 1000C may also adopt one or more conductive pillars 900 in the second tier T2 thereof.

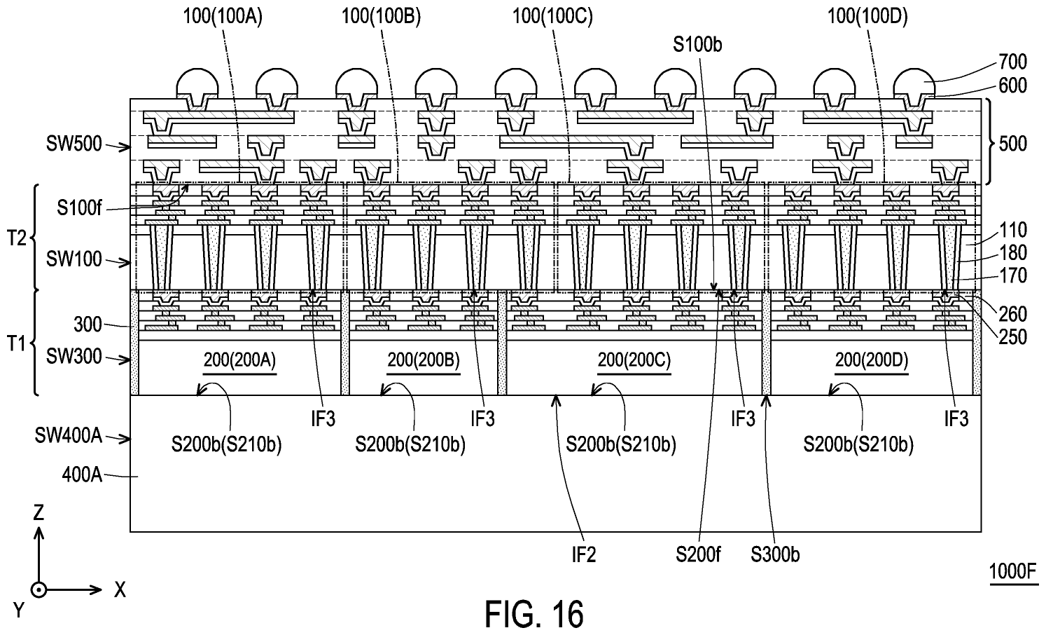

In above embodiments of the semiconductor devices 1000A, 1000B, 1000C, 1000D and 1000E, the semiconductor dies 200 (e.g., 200A, 200B, 200C and 200D) included in the first tier T1 are bonded to the semiconductor dies 100 (e.g., 100A, 100B, 100C and 100D) included in the second tier T2 through a manner of face-to-face configuration. However, the disclosure is not limited thereto. In some alternative embodiments, the semiconductor dies 200 included in the first tier T1 are bonded to the semiconductor dies 100 included in the second tier T2 through a manner of face-to-back configuration, see FIG. 16. FIG. 16 is a schematic cross-sectional view showing a semiconductor device 1000F in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein. For example, the semiconductor device 1000F of FIG. 16 and the semiconductor device 1000A of FIG. 11 are similar; and the difference is that, in the semiconductor device 1000F depicted in FIG. 16, the semiconductor dies 100 included in the second tier T2 are upside down in the direction Z, where the semiconductor dies 200 are connected to the semiconductor dies 100 through bonding the front sides S200f of the semiconductor dies 200 to the back sides S100b of the semiconductor dies 100.

For example, the semiconductor dies 200 in the first tier Ti are bonded to the semiconductor dies 100 in the second tier T2 through physically connecting (e.g., directly contacting) the protection layer 260 and the semiconductor substrate 110 and physically connecting (e.g., directly contacting) the connecting vias 250 and the conductive pillars 170, with or without physically connecting (e.g., directly contacting) the protection layer 260 and the conductive pillars 170 and/or physically connecting (e.g., directly contacting) the connecting vias 250 and the semiconductor substrate 110. In other words, as shown in FIG. 16, for example, the semiconductor dies 200 are electrically connected to and electrically communicated to the semiconductor dies 100 through the connecting vias 250 and the conductive pillars 170. In other words, a bonding interface IF3 between the semiconductor dies 200 (e.g., 200A, 200B, 200C and 200D) and the semiconductor dies 100 (e.g., 100A, 100B, 100C and 100D) includes a dielectric-to-dielectric bonding interface (or a dielectric-to-dielectric bonding region) (e.g., an oxide-to-oxide bonding interface, a nitride-to-nitride bonding interface, or an oxide-to-nitride bonding interface) and a metal-to-metal bonding interface (or a metal-to-metal bonding region) (e.g., a copper-to-copper bonding interface), with or without a dielectric-to-metal bonding interface. In some embodiments, a sidewall of the semiconductor device 1000F includes a sidewall SW500 of the redistribution circuit structure 500, a sidewall SW100 of the semiconductor dies 100 (being connected to each other), a sidewall SW300 of the insulating encapsulation 300 in the first tier Ti, and a sidewall SW400A of the supporting structure 400A. For example, as shown in FIG. 16, the sidewall SW500 of the redistribution circuit structure 500, the sidewall SW100 of the semiconductor dies 100 (being connected to each other), the sidewall SW300 of the insulating encapsulation 300, and the sidewall SW400A of the supporting structure 400A are substantially aligned with each other.

The semiconductor device 1000F may be formed by, but not limited to, providing a wafer W1 including a plurality of semiconductor dies 100 (e.g., over the carrier 50) (similar to the processes of FIG. 1 and FIG. 4), where the front side of the wafer W1 is facing toward the carrier 50 and not accessibly revealed; thinning the wafer W1 until TSVs (e.g., 170) of the semiconductor dies 100 being accessibly revealed (similar to the process of FIG. 9); providing a wafer W2 including a plurality of semiconductor dies 200 (similar to the process of FIG. 2); dicing the wafer W2 to form individual and separated semiconductor dies 200 (similar to the process of FIG. 3); placing the semiconductor dies 200 over the back sides S100b of the semiconductor dies 100 of the wafer W1 (e.g., in a face-to-back configuration) (similar to the process of FIG. 4); bonding the semiconductor dies 200 to the semiconductor dies 100 (e.g., through a chip-on-wafer bonding process) (similar to the process of FIG. 4), where the semiconductor dies 200 are physically connected to and electrically coupled (and communicated) to the semiconductor dies 100, respectively; laterally encapsulating the semiconductor dies 200 in the insulating encapsulation 300 to form the first tier T1 (similar to the processes of FIG. 5 and FIG. 6); thinning the semiconductor dies 200 in the first tier T1 (similar to the process of FIG. 6); bonding a supporting structure 400A onto the back sides of the semiconductor dies 200 in the first tier T1 (similar to the process of FIG. 7); revealing the front side of the wafer W1 (e.g., by debonding the carrier 50) (similar to the process of FIG. 8); forming a redistribution circuit structure 500 over the front side of the wafer W1 (similar to the process of FIG. 10), the redistribution circuit structure 500 being electrically coupled to the semiconductor dies 100 though connecting vias (e.g., 150) thereof; optionally forming UBM patterns 600 over the redistribution circuit structure 500 and electrically connected thereto (similar to the process of FIG. 11); optionally forming conductive terminals 700 over the UBM patterns 600 and electrically connected thereto (similar to the process of FIG. 11); and performing a dicing (or singulation) process to cut through the redistribution circuit structure 500, the wafer W1, the insulating encapsulation 300 of the first tier T1 and the supporting structure 400A (similar to the process of FIG. 11).

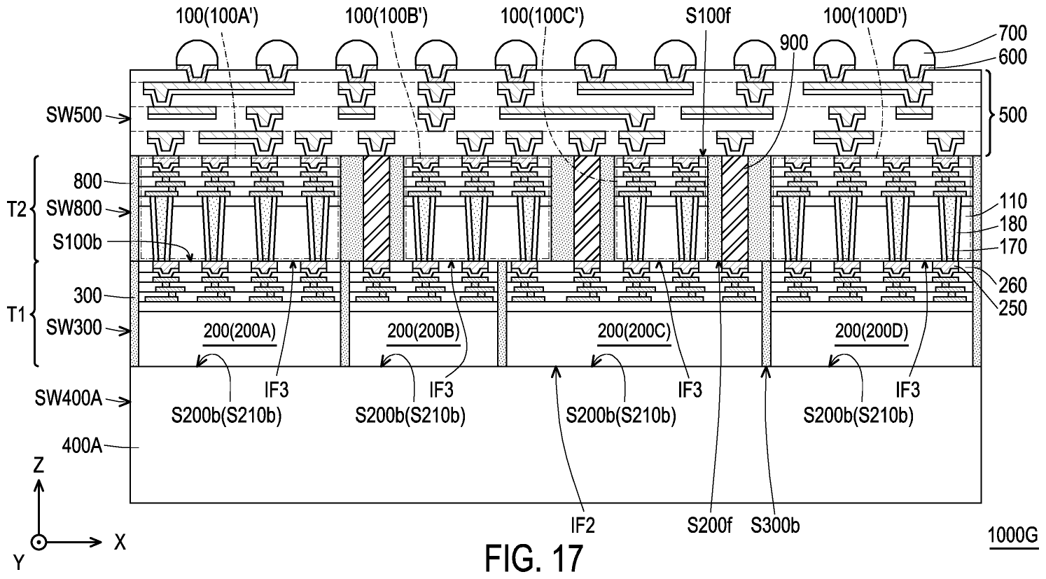

However, the disclosure is not limited thereto. As alternatives, in the disclosure, the semiconductor dies 200 may be bonded to the semiconductor dies 100 in a manner of face-to-back configuration, through a wafer-on-wafer bonding process (as discussed in the semiconductor device 1000B of FIG. 12), a wafer-on-chip bonding process (as discussed in the semiconductor device 1000C of FIG. 13), or a chip-on-chip bonding process (as discussed in the semiconductor device 1000D of FIG. 14), with or without adopting the conductive pillars 900 described in FIG. 15. FIG. 17 is a schematic cross-sectional view showing a semiconductor device 1000G in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein. For example, the semiconductor device 1000G of FIG. 17 and the semiconductor device 1000F of FIG. 16 are similar; and the difference is that, in the semiconductor device 1000G depicted in FIG. 17, the semiconductor dies 100 (e.g., 100A, 100B′, 1000C′, 1000D) included in the second tier T2 are laterally spacing from each other through an insulating encapsulation 800. As shown in FIG. 17, the semiconductor dies 100 and the conductive pillars 900 are laterally spacing from each other and are physically separated by the insulating encapsulation 800, where the conductive pillars 900 provide further electrical connection between the redistribution circuit structure 500 and the semiconductor dies 200 in the first tier T1, for example. The formation and material of the semiconductor device 1000G can refer to the formations and materials of the semiconductor devices 1000C and 1000F as described in FIG. 13 and FIG. 16, and thus are not repeated herein for brevity.

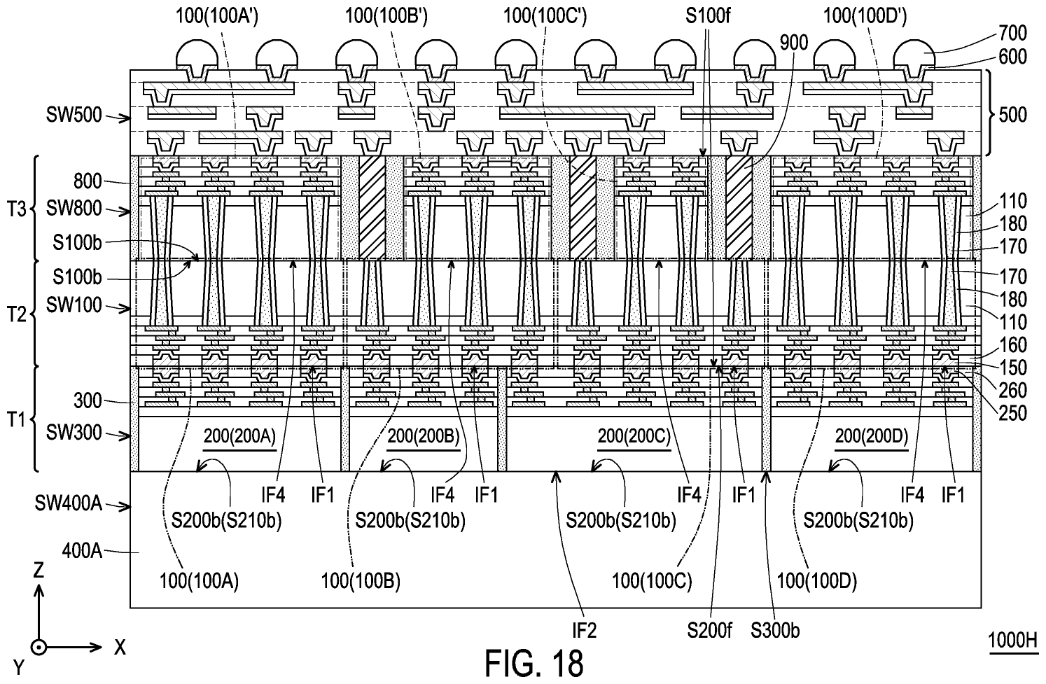

In above embodiments of the semiconductor devices 1000A, 1000B, 1000C, 1000D, 1000E, 1000F and 1000G, there are a die stack of two tiers T1 and T2 being interposed between the supporting structure 400A and the redistribution circuit structure 500. However, the disclosure is not limited thereto. As an alternative, in the semiconductor device of the disclosure, a die stack of more than two tiers may be interposed between the supporting structure 400A and the redistribution circuit structure 500, see FIG. 18. FIG. 18 is a schematic cross-sectional view showing a semiconductor device 1000H in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein. For example, the semiconductor device 1000H of FIG. 18 and the semiconductor device 1000A of FIG. 11 are similar; and the difference is that, in the semiconductor device 1000H depicted in FIG. 18, an addition tier (e.g., a third tier T3) is included in the die stack. Referring to FIG. 18, in some embodiments, the semiconductor device 1000H includes a supporting structure 400A, a die stacking (including a first tier T1, a second tier T2 and a third tier T3) disposed on the supporting structure 400A, a redistribution circuit structure 500 disposed on the die stack and a plurality of conductive terminals 700 disposed over the redistribution circuit structure 500 through UBM patterns 600, where the die stack is between the redistribution circuit structure 500 and the supporting structure 400A, and the redistribution circuit structure 500 is between the die stack and the conductive terminals 700. In some embodiments, the UBM patterns 600 are physically connected to and electrically connected to the redistribution circuit structure 500 and the conductive terminals 700. The UBM patterns 600 and/or the conductive terminals 700 may be omitted. In some embodiments, the conductive terminals 700 are electrically coupled to the redistribution circuit structure 500 through the UBM patterns 600. The details, formations and materials of the supporting structure 400A, the first tier T1 (including semiconductor dies 100A-100D) and the second tier T2 (including semiconductor dies 200A-200D) of the die stack, the redistribution circuit structure 500, the UBM patterns 600, and the conductive terminals 700 are previously discussed in FIG. 1 through FIG. 11, and thus are not repeated herein for brevity.

In some embodiments, the additional tier includes the third tier T3, where the third tier T3 is disposed between the second tier T2 and the redistribution circuit structure 500. As shown in FIG. 18, the third tier T3 may include a plurality of semiconductor dies 100 (e.g., semiconductor dies 100A′, 100B′, 100C′ and 100D′), a plurality of conductive pillars 900 laterally next to the semiconductor dies 100 (e.g., semiconductor dies 100A′, 100B′, 100C′ and 100D′), and an insulating encapsulation 800 laterally encapsulating the semiconductor dies 100 (e.g., semiconductor dies 100A′, 100B′, 100C′ and 100D′) and the conductive pillars 800. The semiconductor dies 100 (e.g., 100A′, 100B′, 100C′ and 100D′) and the conductive pillars 900 in the third tier T3 are electrically connected to the redistribution circuit structure 500 and the semiconductor dies 100 (e.g., 100A, 100B, 100C and 100D) in the second tier T2, for example. In some embodiments, the redistribution circuit structure 500 is electrically connected to the semiconductor dies 100 (e.g., 100A, 100B, 100C and 100D) in the second tier T2 through the semiconductor dies 100 (e.g., 100A′, 100B′, 100C′ and 100D′) and some of the conductive pillars 900 in the third tier T3. In some embodiments, the redistribution circuit structure 500 is electrically connected to the semiconductor dies 100 (e.g., 100A, 100B, 100C and 100D) in the second tier T2 through the semiconductor dies 100 (e.g., 100A′, 100B′, 100C′ and 100D′) in the third tier T3. In some embodiments, the redistribution circuit structure 500 is electrically connected to the semiconductor dies 100 (e.g., 100A, 100B, 100C and 100D) in the second tier T2 through some of the conductive pillars 900 in the third tier T3.

In some embodiments, some of the conductive terminals 700 are electrically coupled to the semiconductor die 100A′ in the third tier T3 through some of the UBM patterns 600 and the redistribution circuit structure 500. In some embodiments, some of the conductive terminals 700 are electrically coupled to the semiconductor die 100B′ in the third tier T3 through some of the UBM patterns 600 and the redistribution circuit structure 500. In some embodiments, some of the conductive terminals 700 are electrically coupled to the semiconductor die 100C′ in the third tier T3 through some of the UBM patterns 600 and the redistribution circuit structure 500. In some embodiments, some of the conductive terminals 700 are electrically coupled to the semiconductor die 100D′ in the third tier T3 through some of the UBM patterns 600 and the redistribution circuit structure 500. In some embodiments, some of the conductive terminals 700 are electrically coupled to the conductive pillars 900 in the third tier T3 through some of the UBM patterns 600 and the redistribution circuit structure 500.

In some embodiments, some of the conductive terminals 700 are electrically coupled to the semiconductor die 100A in the second tier T2 through some of the UBM patterns 600, the redistribution circuit structure 500 and the semiconductor die 100A′ in the third tier T3. In some embodiments, some of the conductive terminals 700 are electrically coupled to the semiconductor die 100B in the second tier T2 through some of the UBM patterns 600, the redistribution circuit structure 500 and the semiconductor die 100B′ in the third tier T3. In addition, some of the conductive terminals 700 may be electrically coupled to the semiconductor die 100B in the second tier T2 through some of the UBM patterns 600, the redistribution circuit structure 500 and the conductive pillars 900 in the third tier T3. In some embodiments, some of the conductive terminals 700 are electrically coupled to the semiconductor die 100C in the second tier T2 through some of the UBM patterns 600, the redistribution circuit structure 500 and the semiconductor die 100C′ in the third tier T3. In addition, some of the conductive terminals 700 may be electrically coupled to the semiconductor die 100C in the second tier T2 through some of the UBM patterns 600, the redistribution circuit structure 500 and the conductive pillars 900 in the third tier T3. In some embodiments, some of the conductive terminals 700 are electrically coupled to the semiconductor die 100D in the second tier T2 through some of the UBM patterns 600, the redistribution circuit structure 500 and the semiconductor die 100D′ in the third tier T3.

In some embodiments, some of the conductive terminals 700 are electrically coupled to the semiconductor die 200A through some of the UBM patterns 600, the redistribution circuit structure 500, the semiconductor die 100A′ in the third tier T3 and the semiconductor die 100A in the second tier T2. In some embodiments, some of the conductive terminals 700 are electrically coupled to the semiconductor die 200B through some of the UBM patterns 600, the redistribution circuit structure 500, the semiconductor die 100B′ in the third tier T3 and the semiconductor die 100B in the second tier T2. In addition, some of the conductive terminals 700 are electrically coupled to the semiconductor die 200B through some of the UBM patterns 600, the redistribution circuit structure 500, the conductive pillars 900 in the third tier T3 and the semiconductor die 100B in the second tier T2. In some embodiments, some of the conductive terminals 700 are electrically coupled to the semiconductor die 200C through some of the UBM patterns 600, the redistribution circuit structure 500, the semiconductor die 100B′ in the third tier T3 and the semiconductor die 100B in the second tier T2. In addition, some of the conductive terminals 700 are electrically coupled to the semiconductor die 200C through some of the UBM patterns 600, the redistribution circuit structure 500, the conductive pillars 900 in the third tier T3 and the semiconductor die 100B in the second tier T2. In some embodiments, some of the conductive terminals 700 are electrically coupled to the semiconductor die 200C through some of the UBM patterns 600, the redistribution circuit structure 500, the semiconductor die 100C′ in the third tier T3 and the semiconductor die 100C in the second tier T2. In addition, some of the conductive terminals 700 are electrically coupled to the semiconductor die 200C through some of the UBM patterns 600, the redistribution circuit structure 500, the conductive pillars 900 in the third tier T3 and the semiconductor die 100C in the second tier T2. In some embodiments, some of the conductive terminals 700 are electrically coupled to the semiconductor die 200D through some of the UBM patterns 600, the redistribution circuit structure 500, the semiconductor die 100D′ in the third tier T3 and the semiconductor die 100D in the second tier T2.

As illustrated in FIG. 18, the semiconductor dies 100 (e.g., 100A′, 100B′, 100C′ and 100D′) in the third tier T3 may be bonded to the semiconductor dies 100 (e.g., 100A, 100B, 100C and 100D) in the second tier T2 in a manner of back-to-back configuration. In alternative embodiments, the semiconductor dies 100 in the third tier T3 may be bonded to the semiconductor dies 100 in the second tier T2 in a manner of face-to-back configuration. In further alternative embodiments, the semiconductor dies 100 in the third tier T3 may be bonded to the semiconductor dies 100 in the second tier T2 in a manner of back-to-face configuration. In yet further alternative embodiments, the semiconductor dies 100 in the third tier T3 may be bonded to the semiconductor dies 100 in the second tier T2 in a manner of face-to-face configuration.

For example, the semiconductor dies 100 in the third tier T3 are bonded to the semiconductor dies 100 in the second tier T2 through physically connecting (e.g., directly contacting) the semiconductor substrate 110 in the third tier T3 and the semiconductor substrate 110 in the second tier T2 and physically connecting (e.g., directly contacting) the conductive pillars 170 in the third tier T3 and the conductive pillars 170 in the second tier T2, with or without physically connecting (e.g., directly contacting) the semiconductor substrate 110 in the third tier T3 and the conductive pillars 170 in the second tier T2 and/or physically connecting (e.g., directly contacting) the semiconductor substrate 110 in the second tier T2 and the conductive pillars 170 in the third tier T3. In other words, as shown in FIG. 18, for example, t the semiconductor dies 100 in the third tier T3 are electrically connected to and electrically communicated to the semiconductor dies 100 in the second tier T2 through the conductive pillars 170 included in the semiconductor dies 100 of the second tier T2 and the third tier T3. In other words, a bonding interface IF4 between the semiconductor dies 100 (e.g., 100A′, 100B′, 100C′ and 100D′) in the third tier T3 and the semiconductor dies 100 (e.g., 100A, 100B, 100C and 100D) in the second tier T2 includes a dielectric-to-dielectric bonding interface (or a dielectric-to-dielectric bonding region) (e.g., an oxide-to-oxide bonding interface, a nitride-to-nitride bonding interface, or an oxide-to-nitride bonding interface) and a metal-to-metal bonding interface (or a metal-to-metal bonding region) (e.g., a copper-to-copper bonding interface), with or without a dielectric-to-metal bonding interface. In some embodiments, a sidewall of the semiconductor device 1000H includes a sidewall SW500 of the redistribution circuit structure 500, a sidewall SW800 of the insulating encapsulation 800 in the third tier T3, a sidewall SW100 of the semiconductor dies 100 (being connected to each other), a sidewall SW300 of the insulating encapsulation 300 in the first tier T1, and a sidewall SW400A of the supporting structure 400A. For example, as shown in FIG. 18, the sidewall SW500 of the redistribution circuit structure 500, the sidewall SW800 of the insulating encapsulation 800, the sidewall SW100 of the semiconductor dies 100 (being connected to each other), the sidewall SW300 of the insulating encapsulation 300, and the sidewall SW400A of the supporting structure 400A are substantially aligned with each other.

The semiconductor device 1000H may be formed by, but not limited to, forming the conductive pillars 900 over the carrier 500 (similar to the process previously described in FIG. 15); providing a wafer including a plurality of semiconductor dies 100 (e.g., 100A′ through 100D′) (similar to the process of FIG. 1); dicing the wafer to form individual and separated semiconductor dies 100 (e.g., 100A′ through 100D′) (similar to the process of FIG. 3); placing the semiconductor dies 100 (e.g., 100A′ through 100D′) over the carrier 50 (similar to the process of FIG. 4) next to the conductive pillars 900; laterally encapsulating the semiconductor dies 100 (e.g., 100A′ through 100D′) and the conductive pillars 900 in the insulating encapsulation 800 to form the third tier T3 (similar to the processes of FIG. 5 and FIG. 6); providing a wafer W1 including a plurality of semiconductor dies 100 (e.g., 100A through 100D) (e.g., over the carrier 50) (similar to the processes of FIG. 1 and FIG. 4); bonding the semiconductor dies 100 (e.g., 100A through 100D) of the wafer W1 to the semiconductor dies 100 (e.g., 100A′ through 100D′) in the third tier T3 (e.g., through a wafer-on-chip bonding process) (similar to the process of FIG. 4), where the semiconductor dies 100 (e.g., 100A through 100D) are physically connected to and electrically coupled (and communicated) to the semiconductor dies 100 (e.g., 100A′ through 100D′), respectively; providing a wafer W2 including a plurality of semiconductor dies 200 (similar to the process of FIG. 2); dicing the wafer W2 to form individual and separated semiconductor dies 200 (similar to the process of FIG. 3); placing the semiconductor dies 200 over the semiconductor dies 100 in the second tier T2 (e.g., in a face-to-face configuration) (similar to the process of FIG. 4); bonding the semiconductor dies 200 to the semiconductor dies 100 (e.g., through a chip-on-chip bonding process) (similar to the process of FIG. 4), where the semiconductor dies 200 are physically connected to and electrically coupled (and communicated) to the semiconductor dies 100, respectively; laterally encapsulating the semiconductor dies 200 in the insulating encapsulation 300 to form the first tier T1 (similar to the processes of FIG. 5 and FIG. 6); thinning the semiconductor dies 200 in the first tier T1 (similar to the process of FIG. 6); bonding a supporting structure 400A onto the back sides of the semiconductor dies 200 in the first tier T1 (similar to the process of FIG. 7); revealing the bottom surface S1 of the semiconductor dies 100 in the second tier T2 (e.g., by debonding the carrier 50) (similar to the process of FIG. 8); thinning the semiconductor dies 100 in the second tier T2 until TSVs (e.g., 170) of the semiconductor dies 100 being accessibly revealed (similar to the process of FIG. 9); forming a redistribution circuit structure 500 over the semiconductor dies 100 in the second tier T2 (similar to the process of FIG. 10), the redistribution circuit structure 500 being electrically coupled to the semiconductor dies 100 though the TSVs (e.g., 170); optionally forming UBM patterns 600 over the redistribution circuit structure 500 and electrically connected thereto (similar to the process of FIG. 11); optionally forming conductive terminals 700 over the UBM patterns 600 and electrically connected thereto (similar to the process of FIG. 11); and performing a dicing (or singulation) process to cut through the redistribution circuit structure 500, the insulating encapsulation 800 in the third tier Ti, the wafer W1, the insulating encapsulation 300 in the first tier T1 and the supporting structure 400A (similar to the process of FIG. 11). During bonding the semiconductor dies 100 (e.g., 100A through 100D) of the wafer W1 to the semiconductor dies 100 (e.g., 100A′ through 100D′) in the third tier T3 (e.g., through a wafer-on-chip bonding process), the semiconductor dies 100 (e.g., 100A′ through 100D′) may be further bonded to the conductive pillars 900 and are thus physically connected to and electrically coupled to the conductive pillars 900. The disclosure is not limited thereto; in some alternative embodiments, in the above formation, placing the conductive pillars 900 over the carrier 500 is prior to laterally encapsulating the semiconductor dies 100 (e.g., 100A′ through 100D′) and the conductive pillars 900 in the insulating encapsulation 800 to form the third tier T3 and after placing the semiconductor dies 100 (e.g., 100A′ through 100D′) over the carrier 50 (similar to the process of FIG. 4).

As shown in FIG. 18, the additional tier includes one additional tier, e.g., the third tier T3 for illustrative purposes, the disclosure is not limited thereto. The number of the additional tier may be one or more than one, which can be selected and/or designated based on demand and design layout. In some embodiments, the configuration of each of one or more additional tiers independently can be similar to or substantially identical to the configuration of one of the first tier T1, the second tier T2 and modifications thereof included in the semiconductor devices 1000A, 1000B, 1000C, 1000D, 1000E, 1000F, 1000G, as long as the vertical electrical connections among the tiers of the die stack and electrical connections between the die stack and the redistribution circuit structure 500 are properly established.

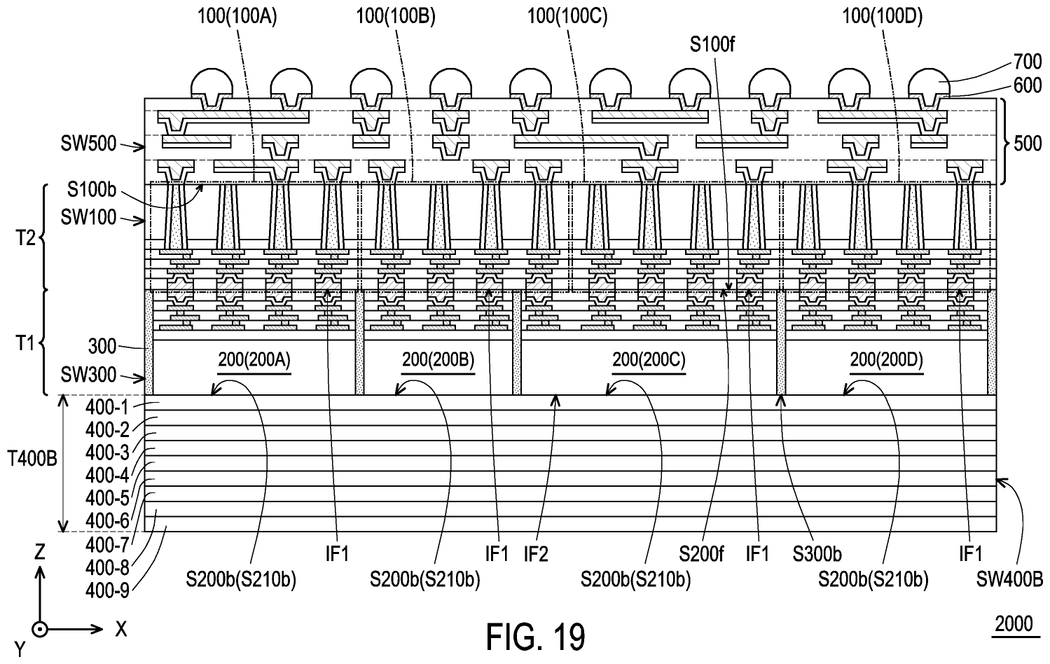

In some embodiments, the supporting structure 400A of a single-layer structure in the semiconductor devices 1000A, 1000B, 1000C, 1000D, 1000E, 1000F, 1000G, 1000H and modifications thereof may be substituted with a supporting structure 400B of a multi-layer structure. FIG. 19 is a schematic cross-sectional view showing a semiconductor device 2000 in accordance with alternative embodiments of the disclosure. The elements similar to or substantially the same as the elements described above will use the same reference numbers, and certain details or descriptions of the same elements (e.g., the formations and materials) and the relationship thereof (e.g., the relative positioning configurations and electrical connections) will not be repeated herein. For example, the semiconductor device 2000 of FIG. 19 and the semiconductor device 1000A of FIG. 11 are similar; and the difference is that, in the semiconductor device 2000 depicted in FIG. 19, the supporting structure 400B is included, instead of the supporting structure 400A. In the disclosure, the supporting structure 400B may also be referred to as a supporting carrier, a high performance carrier, or a high performance supporting structure.

Referring to FIG. 19, in some embodiments, the semiconductor device 2000 includes a supporting structure 400B, a die stacking (including a first tier T1 and a second tier T2) disposed on the supporting structure 400B, a redistribution circuit structure 500 disposed on the die stack and a plurality of conductive terminals 700 disposed over the redistribution circuit structure 500 through UBM patterns 600, where the die stack is between the redistribution circuit structure 500 and the supporting structure 400B, and the redistribution circuit structure 500 is between the die stack and the conductive terminals 700. In some embodiments, the UBM patterns 600 are physically connected to and electrically connected to the redistribution circuit structure 500 and the conductive terminals 700. The UBM patterns 600 and/or the conductive terminals 700 may be omitted. In some embodiments, the conductive terminals 700 are electrically coupled to the redistribution circuit structure 500 through the UBM patterns 600. In some embodiments, the first tier T1 is disposed between the second tier T2 and the supporting structure 400B, and the second tier T2 is disposed between the first tier T1 and the redistribution circuit structure 500. The details, formations and materials of the first tier T1 (including semiconductor dies 100A-100D) and the second tier T2 (including semiconductor dies 200A-200D) of the die stack, the redistribution circuit structure 500, the UBM patterns 600, and the conductive terminals 700 are previously discussed in FIG. 1 through FIG. 11, and thus are not repeated herein for brevity.

In some embodiments, the supporting structure 400B is disposed on (e.g., in physical contact with) the semiconductor dies 200 and the insulating encapsulation 300 laterally encapsulating the semiconductor dies 200. For example, the supporting structure 400B is bonded to the semiconductor dies 200 by performing a thermal process to establish bonds (e.g., covalent bonds) between the supporting structure 400B and the semiconductor dies 200 (e.g., at the interface of the supporting structure 400B and the semiconductor dies 200). The supporting structure 400B may be bonded to the semiconductor dies 200 by fusion bonding. In the case, an interface IFS is between the supporting structure 400B and the semiconductor dies 200. The interface IFS may be a fusion bonding interface (or a fusion bonding region). In some embodiments, the supporting structure 400B is thermally coupled to the semiconductor dies 200. In some embodiments, the supporting structure 400B is thermally coupled to and electrically isolated from the semiconductor dies 200. In the disclosure, the supporting structure 400B may also be referred to as a supporting structure, a high performance carrier, or a high performance supporting structure.

For example, the supporting structure 400B is pre-fabricated. The supporting structure 400B may be a multi-layer structure, such as in a form of composite structure, as shown in FIG. 18. In some embodiments, the supporting structure 400B is made of ceramic materials, semiconductor materials, polymer materials, metallic materials (such as metals or metal alloys), dielectric materials or combinations thereof. As shown in FIG. 19, the supporting structure 400B may include a plurality of sub-layers (e.g., 400-1, 400-2, 400-3, 400-4, 400-5, 400-6, 400-7, 400-8, and 400-9), where any two immediately adjacent sub-layers (e.g., 400-1 and 400-2; 400-2 and 400-3; 400-3 and 400-4; 400-4 and 400-5; 400-5 and 400-6; 400-6 and 400-7; 400-7 and 400-8; or 400-8 and 400-9) of the sub-layers (e.g., 400-1, 400-2, 400-3, 400-4, 400-5, 400-6, 400-7, 400-8, and 400-9) may be made of a same material or different materials based on the demand and design layout. In a non-limiting example, thicknesses of the sub-layers (e.g., 400-1, 400-2, 400-3, 400-4, 400-5, 400-6, 400-7, 400-8, and 400-9) may be the same. In another non-limiting example, thicknesses of the sub-layers (e.g., 400-1, 400-2, 400-3, 400-4, 400-5, 400-6, 400-7, 400-8, and 400-9) may be different, in part or all. The disclosure is not limited thereto.

In some embodiments, the supporting structure 400B has a CTE approximately ranging from 2 ppm/K to 4 ppm/K. In a non-limiting example, the CTE of the supporting structure 400B may be about 2.0 ppm/K, 2.1 ppm/K, 2.2 ppm/K, 2.3 ppm/K, 2.4 ppm/K, 2.5 ppm/K, 2.6 ppm/K, 2.7 ppm/K, 2.8 ppm/K, 2.9 ppm/K, 3.0 ppm/K, 3.1 ppm/K, 3.2 ppm/K, 3.3 ppm/K, 3.4 ppm/K, 3.5 ppm/K, 3.6 ppm/K, 3.7 ppm/K, 3.8 ppm/K, 3.9 ppm/K, or 4.0 ppm/K, although other suitable CTE value may alternatively be utilized. Owing to the supporting structure 400B (having the CTE value closer to those of the semiconductor substrates 210 of the semiconductor dies 200), the warpage of the semiconductor device 2000 during the manufacture thereof can be suppressed.

In some embodiments, the supporting structure 400B has a Young's modulus (E) greater than 150 GPa. In a non-limiting example, the Young's modulus of the supporting structure 400B may be greater than 150 GPa and less than or substantially equal to 5000 GPa, greater than 150 GPa and less than or substantially equal to 4000 GPa, greater than 150 GPa and less than or substantially equal to 3000 GPa, greater than 150 GPa and less than or substantially equal to 2000 GPa, greater than 150 GPa and less than or substantially equal to 1000 GPa, greater than 150 GPa and less than or substantially equal to 900 GPa, greater than 150 GPa and less than or substantially equal to 800 GPa, greater than 150 GPa and less than or substantially equal to 700 GPa, greater than 150 GPa and less than or substantially equal to 600 GPa, greater than 150 GPa and less than or substantially equal to 500 GPa, greater than 150 GPa and less than or substantially equal to 400 GPa, greater than 150 GPa and less than or substantially equal to 300 GPa, although other suitable Young's modulus may alternatively be utilized. Owing to the supporting structure 400B (having the Young's modulus greater than those of the semiconductor substrates 210 of the semiconductor dies 200), the warpage of the semiconductor device 2000 can be suppressed during bonding the semiconductor device 2000 to an external component or element.

In some embodiments, the supporting structure 400B has a thermal conductivity greater than 150W/(m*K). In a non-limiting example, the thermal conductivity of the supporting structure 400B may be greater than greater than 150W/(m*K) and less than or substantially equal to 1000W/(m*K), greater than 150W/(m*K) and less than or substantially equal to 950W/(m*K), greater than 150W/(m*K) and less than or substantially equal to 900W/(m*K), greater than 150W/(m*K) and less than or substantially equal to 850W/(m*K), greater than 150W/(m*K) and less than or substantially equal to 800W/(m*K), greater than 150W/(m*K) and less than or substantially equal to 750W/(m*K), greater than 150W/(m*K) and less than or substantially equal to 700W/(m*K), greater than 150W/(m*K) and less than or substantially equal to 650W/(m*K), greater than 150W/(m*K) and less than or substantially equal to 600W/(m*K), greater than 150W/(m*K) and less than or substantially equal to 550W/(m*K), greater than 150W/(m*K) and less than or substantially equal to 500W/(m*K), greater than 150W/(m*K) and less than or substantially equal to 450W/(m*K), greater than 150W/(m*K) and less than or substantially equal to 400W/(m*K), greater than 150W/(m*K) and less than or substantially equal to 350W/(m*K), greater than 150W/(m*K) and less than or substantially equal to 300W/(m*K), greater than 150W/(m*K) and less than or substantially equal to 250W/(m*K), greater than 150W/(m*K) and less than or substantially equal to 200W/(m*K), although other suitable thermal conductivity may alternatively be utilized. Owing to the supporting structure 400B (having the thermal conductivity greater than those of the semiconductor substrates 210 of the semiconductor dies 200), the heat generated by the semiconductor dies 200 during the operation can be efficiently dissipating to the external environment through the supporting structure 400B.

A thickness T400B of the supporting structure 400B may be approximately ranging from 50 μm to 5 mm, although other suitable thickness may alternatively be utilized. For example, the thickness T400B of the supporting structure 400B is greater than or substantially equal to 50 μm and less than or substantially equal to 5 mm. In a non-limiting example, the thickness T400B of the supporting structure 400B may be greater than or substantially equal to 50 μm and less than or substantially equal to 4 mm. In another non-limiting example, the thickness T400B of the supporting structure 400B may be greater than or substantially equal to 50 μm and less than or substantially equal to 3 mm. In another non-limiting example, the thickness T400B of the supporting structure 400B may be greater than or substantially equal to 50 μm and less than or substantially equal to 2 mm. In another non-limiting example, the thickness T400B of the supporting structure 400B may be greater than or substantially equal to 50 μm and less than or substantially equal to 1 mm. In some embodiments, a material of the supporting structure 400B is different from a material of the semiconductor substrates 110 of the semiconductor dies 100. In some embodiments, a material of the supporting structure 400B is different from a material of the semiconductor substrates 210 of the semiconductor dies 200.

In addition, bonds (e.g., covalent bonds) between the supporting structure 400B and the insulating encapsulation 300 (e.g., at the interface of the supporting structure 400B and the semiconductor dies 200) may be also established. That is, the supporting structure 400B is further bonded to the insulating encapsulation 300, for example.

In some embodiments, a sidewall of the semiconductor device 2000 includes a sidewall SW500 of the redistribution circuit structure 500, a sidewall SW100 of the semiconductor dies 100 (being connected to each other), a sidewall SW300 of the insulating encapsulation 300, and a sidewall SW400B of the supporting structure 400B. For example, as shown in FIG. 19, the sidewall SW500 of the redistribution circuit structure 500, the sidewall SW100 of the semiconductor dies 100 (being connected to each other), the sidewall SW300 of the insulating encapsulation 300, and the sidewall SW400B of the supporting structure 400B are substantially aligned with each other.

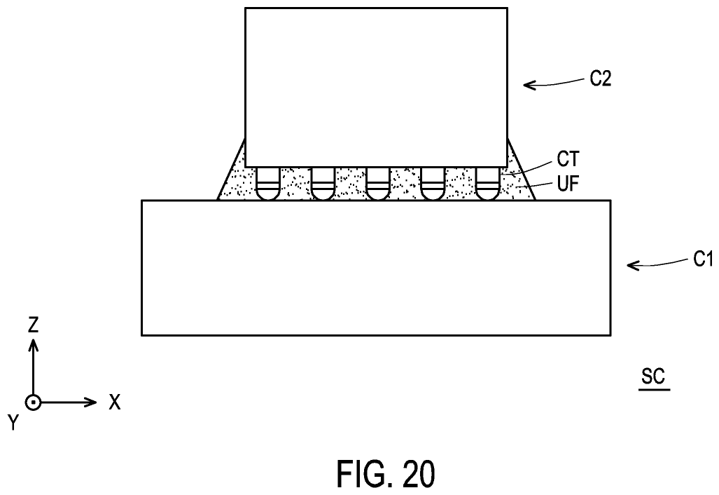

The semiconductor devices 1000A, 1000B, 1000C, 1000D, 1000E, 1000F, 1000G, 1000H, 2000 and modifications thereof may be referred to as System-on-Integrate-Chips (SoICs). In some embodiments, the semiconductor devices 1000A, 1000B, 1000C, 1000D, 1000E, 1000F, 1000G, 1000H, 2000 and modifications thereof may be further mounted onto another electronical component. FIG. 20 is a schematic cross-sectional view showing an application of a semiconductor device (e.g., 1000A, 1000B, 1000C, 1000D, 1000E, 1000F, 1000G, 1000H, 2000 or their modifications) in accordance with some embodiments of the disclosure The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 20, in some embodiments, a component assembly SC including a first component C1 and a second component C2 disposed over the first component C1 is provided. The first component C1 may be or may include a circuit structure, such as a mother board, a package substrate, a printed circuit board (PCB), a printed wiring board, and/or other carrier that is capable of carrying integrated circuits. In some embodiments, the second component C2 mounted on the first component C1 is similar to one of the semiconductor devices 1000A, 1000B, 1000C, 1000D, 1000E, 1000F, 1000G, 1000H, 2000 and/or modifications thereof. For example, one or more second components C2 (e.g., the semiconductor devices 1000A, 1000B, 1000C, 1000D, 1000E, 1000F, 1000G, 1000H, 2000 and/or modifications thereof) may be electrically coupled to the first component C1 through a plurality of terminals CT. The terminals CT may be the conductive terminals 700. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In alternative embodiments, the semiconductor devices 1000A, 1000B, 1000C, 1000D, 1000E, 1000F, 1000G, 1000H, 2000 and/or modifications thereof may be or may be part of an integrated Fan-Out (InFO) package, an InFO package having a Package-on-Package (PoP) structure, a chip-on-wafer-on-substrate (CoWoS) package, a flip chip package of an InFO package, or the like. The disclosure is not limited thereto. Owing to the supporting structure 400A or 400B in the semiconductor device of the disclosure, a reduction (e.g., by more than 5% or about 5%) in the maximum temperature during operating is observed, as compared to a conventional semiconductor device without using the supporting structure 400A or 400B of the disclosure. On the other hand, owing to the supporting structure 400A or 400B in the semiconductor device of the disclosure, a reduction (e.g., by more than 60% or about 60%) in the warpage is observed, as compared to a conventional semiconductor device without using the supporting structure 400A or 400B of the disclosure.

In accordance with some embodiments, a semiconductor device includes a supporting structure, a die stack, and a redistribution circuit structure. The die stack is disposed over the supporting structure and includes a first semiconductor die comprising a substrate and a second semiconductor die, where the first semiconductor die is between the second semiconductor die and the supporting structure, and a material of the supporting structure is different from a material of the substrate of the first semiconductor die. The redistribution circuit structure is disposed over the die stack and electrically coupled to the first semiconductor die and the second semiconductor die.

In accordance with some embodiments, a semiconductor device includes at least one first die, a supporting carrier, a routing structure, and a plurality of terminals. The at least one first die includes a substrate and has a first back side and a first front side opposite to the first back side. The supporting carrier is disposed on the first back side of the at least one first die, where a thermal conductivity of the supporting carrier is greater than a thermal conductivity of the substrate of the at least one first die. The routing structure is disposed on and electrically coupled to the at least one first die. The plurality of terminals are disposed over and electrically coupled to the routing structure.

In accordance with some embodiments, a method of manufacturing a semiconductor device includes the following steps: bonding at least one first die to at least one second die, the at least one first die comprising a substrate and having a first back side and a first front side opposite to the first back side, and the at least one second die being mounted to the first front side of the at least one first die; bonding a supporting carrier to the first back side of the at least one first die, a material of the supporting carrier is different from a material of the substrate of the at least one first die; forming a routing structure on and electrically coupled to the at least one second die; and disposing a plurality of terminals over and electrically coupled to the routing structure, the routing structure being disposed between the plurality of terminals and the at least one second die.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a supporting structure;
a die stack, disposed over the supporting structure and comprising:
a first semiconductor die comprising a substrate; and
a second semiconductor die,
wherein the first semiconductor die is between the second semiconductor die and the supporting structure, and a material of the supporting structure is different from a material of the substrate of the first semiconductor die; and
a redistribution circuit structure, disposed over the die stack and electrically coupled to the first semiconductor die and the second semiconductor die.

2. The semiconductor device of claim 1, wherein the supporting structure is a single-layer structure.

3. The semiconductor device of claim 1, wherein the supporting structure is a multi-layer structure.

4. The semiconductor device of claim 1, wherein the supporting structure is thermally coupled to the first semiconductor die.

5. The semiconductor device of claim 1, wherein the supporting structure is thermally coupled to and electrically isolated from the first semiconductor die.

6. The semiconductor device of claim 1, wherein a Young's modulus of the supporting structure is greater than a Young's modulus of the substrate of the first semiconductor die.

7. The semiconductor device of claim 1, wherein a thermal conductivity of the supporting structure is greater than a thermal conductivity of the substrate of the first semiconductor die.

8. The semiconductor device of claim 1, wherein an interface between the first semiconductor die and the second semiconductor die comprises a metal-to-metal bonding region and a dielectric-to-dielectric bonding region.

9. A semiconductor device, comprising:
at least one first die comprising a substrate, having a first back side and a first front side opposite to the first back side;
a supporting carrier, disposed on the first back side of the at least one first die, wherein a thermal conductivity of the supporting carrier is greater than a thermal conductivity of the substrate of the at least one first die;
a routing structure, disposed on and electrically coupled to the at least one first die; and
a plurality of terminals, disposed over and electrically coupled to the routing structure.

10. The semiconductor device of claim 9, wherein a bonding interface between the at least one first die and the supporting carrier comprises a dielectric-to-dielectric bonding region.

11. The semiconductor device of claim 9, wherein a Young's modulus of the supporting carrier is greater than a Young's modulus of the substrate of the at least one first die.

12. The semiconductor device of claim 9, further comprising:
at least one second die, disposed on the first front side of the at least one first die.

13. The semiconductor device of claim 12, wherein a bonding interface between the at least one first die and the at least one second die comprises a metal-to-metal bonding region and a dielectric-to-dielectric bonding region.

14. The semiconductor device of claim 12, further comprising:
at least one conductive pillar, disposed on the at least one first die and laterally next to the at last one second die; and
an insulating encapsulation, laterally encapsulating the at least one second die and the at least one conductive pillar, wherein the at least one conductive pillar electrically couples the at least one first die and the routing structure.

15. The semiconductor device of claim 12, further comprising:
at least one third die, disposed on and bonded to the at least one second die.

16. The semiconductor device of claim 15, further comprising:
at least one first conductive pillar, disposed on the at least one first die and laterally next to the at last one second die; and
a first insulating encapsulation, laterally encapsulating the at least one second die and the at least one first conductive pillar, wherein the at least one first conductive pillar electrically couples the at least one first die and the routing structure.

17. The semiconductor device of claim 15, further comprising:
at least one second conductive pillar, disposed on the at least one second die and laterally next to the at last one third die; and
a second insulating encapsulation, laterally encapsulating the at least one third die and the at least one second conductive pillar, wherein the at least one second conductive pillar electrically couples the at least one second die and the routing structure.

18. The semiconductor device of claim 17, further comprising:
at least one third conductive pillar, disposed on the at least one first die and laterally next to the at last one second die; and
a third insulating encapsulation, laterally encapsulating the at least one second die and the at least one third conductive pillar, wherein the at least one third conductive pillar electrically couples the at least one first die and the routing structure.

19. A method of manufacturing a semiconductor device, comprising:
bonding at least one first die to at least one second die, the at least one first die comprising a substrate and having a first back side and a first front side opposite to the first back side, and the at least one second die being mounted to the first front side of the at least one first die;
bonding a supporting carrier to the first back side of the at least one first die, a material of the supporting carrier is different from a material of the substrate of the at least one first die;
forming a routing structure on and electrically coupled to the at least one second die; and
disposing a plurality of terminals over and electrically coupled to the routing structure, the routing structure being disposed between the plurality of terminals and the at least one second die.

20. The method of claim 19, wherein the at least one second die has a second back side and a second front side opposite to the second back side,
wherein bonding the at least one first die to the at least one second die comprises:
bonding the second front side of the at least one second die to the first front side of the at least one first die by a dielectric-to-dielectric bonding and a metal-to-metal bonding, or
bonding the second back side of the at least one second die to the first front side of the at least one first die by a dielectric-to-dielectric bonding and a metal-to-metal bonding, and
wherein prior to bonding the supporting carrier to the first back side of the at least one first die and after bonding the at least one first die to the at least one second die, the method further comprises:
thinning down the substrate of the at least one first die from the first back side.
